(19) United States
(12) Patent Application Publication
(10) Pub. No.: US 2021/0020838 A1
(43) Pub. Date: Jan. 21, 2021

(54) COMPOSITE MATERIAL AND PREPARATION METHOD THEREFOR AND QUANTUM DOT LIGHT-EMITTING DIODE

(71) Applicant: TCL TECHNOLOGY GROUP CORPORATION, Huizhou (CN)

(72) Inventor: Huijun QIN, Huizhou (CN)

(21) Appl. No.: 17/039,516

(22) Filed: Sep. 30, 2020

Related U.S. Application Data
(63) Continuation of application No. PCT/CN2019/104762, filed on Sep. 6, 2019.

(30) Foreign Application Priority Data
Sep. 7, 2018 (CN) 201811044363.X
Sep. 7, 2018 (CN) 201811044364.4
Sep. 7, 2018 (CN) 201811046063.5

(51) Int. Cl. H01L 51/00; C09K 11/06; C09K 11/54

(52) U.S. Cl. CPC H01L 51/005; C09K 11/06; H01L 51/502; C09K 2211/10; C09K 11/54

(57) ABSTRACT

A composite material includes a particle, and a halogen ligand and an oil-soluble organic ligand bound on a surface of the particle. The particle is an inorganic semiconductor nanocrystal.

### CROSS-REFERENCE TO RELATED APPLICATIONS

This application is a continuation of International Application No. PCT/CN2019/104762, filed Sep. 6, 2019, which claims priority to Chinese Application Nos. 201811046063.5, 201811044364.4, and 201811044363.X, filed Sep. 7, 2018, the entire contents of all of which are incorporated herein by reference.

### TECHNICAL FIELD

The present disclosure relates to quantum dot light-emitting device field, and more particularly, to a composite material, a preparation method therefor, and a quantum dot light-emitting diode.

### BACKGROUND

In recent years, due to characteristics of high quantum efficiency, high optical purity, and adjustable emission wavelength, etc., colloidal quantum dots have become the most promising new display materials. At present, researchers have been able to prepare quantum dot materials with photoluminescence efficiency up to 100%, which can be widely used in biomarkers, sensor devices and light-emitting diodes (LEDs).

On the other hand, in the preparation process of quantum dot light-emitting diodes, the external quantum efficiency of a device is very low. For example, reported efficiencies of red, green, and blue devices are all lower than 20%. The reason why the photoluminescence efficiency and electroluminescence efficiency of a quantum dot material differ so much is mainly due to a fact that the quantum dot material uses optical excitation but the device uses electrical excitation. In the device structure, the quantum dot light-emitting layer has a relatively high requirement for other functional layers, e.g., electron transport layer and hole transport layer, and only when the other functional layers achieve relatively ideal conditions in terms of, e.g., operation function, transport performance, stability, etc. can high device efficiency and life be obtained. A very important factor that determines the efficiency of a quantum dot device is that the electron transport rate and the hole transport rate are balanced. In the existing device structure, the electron transport rate is generally greater than the hole transport rate, and it is difficult to achieve a balance between the two, resulting in a relatively low device efficiency and service life.

Therefore, the existing technology needs to be improved and developed.

### SUMMARY

In accordance with the disclosure, there is provided a composite material including a particle, and a halogen ligand and an oil-soluble organic ligand bound on the surface of the particle. The particle includes an inorganic semiconductor nanocrystal.

Also in accordance with the disclosure, there is provided a composite material preparation method including dispersing a cationic precursor and an oil-soluble organic ligand into a first solvent and heating at a first temperature to obtain a first mixture, dispersing an anionic precursor into a second solvent and heating at a second temperature to obtain a second mixture, and while heating the first mixture at a third temperature, injecting the second mixture for a crystal growth of an inorganic semiconductor nanocrystal to obtain a composite material. The cationic precursor includes a metal halide. The anionic precursor includes an organic alcohol. The third temperature is higher than the first temperature and the second temperature.

Also in accordance with the disclosure, there is provided a quantum dot light-emitting diode including an anode, a cathode, and a laminate disposed between the anode and the cathode. The laminate includes a quantum dot light-emitting layer disposed near the anode, and an electron transport layer disposed near the cathode. A material of the electron transport layer includes a particle including an inorganic semiconductor nanocrystal, and a halogen ligand and an oil-soluble organic ligand bound on a surface of the particle.

### BRIEF DESCRIPTION OF THE DRAWINGS

FIG. 1 is a schematic structural diagram of a quantum dot light-emitting diode according to the present disclosure.

FIG. 2 is a schematic structural diagram of an electron transport layer in FIG. 1.

FIG. 3 is another schematic structural diagram of an electron transport layer in FIG. 1.

FIG. 4 is a TEM image of a product according to an embodiment of the disclosure.

FIG. 5 is an absorption and emission spectrum of the product according to an embodiment of the disclosure.

### DETAILED DESCRIPTION OF THE EMBODIMENTS

The present disclosure provides a composite material and its preparation method, and a quantum dot light-emitting diode. In order to make the purpose, technical solutions, and effects of the disclosure clearer and less ambiguous, the disclosure will be described in further detail below. It should be understood that the specific embodiments described herein are only for illustrative purpose, and are not intended to limit the present disclosure.

The present disclosure provides a composite material including a particle, and a halogen ligand and oil-soluble organic ligand bound on the surface of the particle. The particle is an inorganic semiconductor nanocrystal. The composite material is an electron transport material applied to a light-emitting diode.

In the composite material provided by the present disclosure, the composite material can be used as an electron transport material of a light-emitting diode (e.g., a quantum dot light-emitting diode, or an organic light-emitting diode). The surface has mixed ligands of the halogen ligand and the oil-soluble organic ligand, and the oil-soluble organic ligand makes the composite material oil-soluble. In the oil-soluble composite material of the present disclosure, the halogen ligand can improve the electron transport performance, and the oil-soluble organic ligand can effectively reduce the electron transport rate, so that the electron transport performance of the material may be adjusted, thereby adjusting the electron transport rate and the hole transport rate in a device, and hence improving the light-emitting efficiency of a light-emitting layer. The oil-soluble organic ligand bound on the surface of the particle acts as passivating the surface and hence there are fewer surface defects.

In the composite material provided by the present disclosure, the composite material has no emission in the visible band, thereby ensuring that the composite material can be used as an electron transport material.

In some embodiments, the particle size of an inorganic semiconductor nanocrystal is 2-7 nm. The inorganic semiconductor nanocrystal has a small size and the particles are uniform. The particles have a good dispersibility in the solvent and the solution formed by dissolving the particles in the solvent is clear without a precipitation.

In some embodiments, the inorganic semiconductor nanocrystal is a metal oxide particle selected from a ZnO particle, a CdO particle, a SnO particle, or a GeO particle, but not limited thereto. In another embodiment, the inorganic semiconductor nanocrystal is a metal sulfide particle selected from a ZnS particle, a SnS particle, or a GeS particle, but not limited thereto. In the embodiments of the present disclosure, the inorganic semiconductor nanocrystal including the material described above has no emission in the visible band, and can be used as an electron transport material that does not affect the emission color of the light-emitting layer of a quantum dot device.

In some embodiments, the halogen ligand includes one or more of a chloride ion, a bromide ion, and an iodide ion.

Further, in some embodiments, the halogen ligand is a chloride ion. Since the atomic radius of chlorine is small compared to bromine and iodine, when it is used as a surface ligand on the surface of the particle, the distance that an electron needs to travel during transport is small, which can improve the electron transportability.

In some embodiments, the oil-soluble organic ligand includes one or more of a linear organic ligand with a carbon number of eight or more, a secondary or tertiary amine having a side chain with a carbon number of four or more, a substituted or unsubstituted alkylaminophosphine, a substituted or unsubstituted alkoxyphosphine, a substituted or unsubstituted silylphosphine, and an alkylphosphine having a side chain with a carbon number of four or more, but not limited thereto.

Further, in some embodiments, the linear organic ligand with a carbon number of eight or more includes one or more of an organic carboxylic acid with a carbon number of eight or more, a thiol with a carbon number of eight or more, an organic phosphoric acid with a carbon number of eight or more, and a primary amine with a carbon number of eight or more, but not limited thereto. Specifically, the organic carboxylic acid with a carbon number of eight or more includes one or more of a caprylic acid, a nonanoic acid, a capric acid, an undecyl acid, a dodecyl acid, a tridecyl acid, a tetradecyl acid, a hexadecyl, and an octadecyl acid, etc. Specifically, the thiol with a carbon number of eight or more is selected form one or more of an octyl mercaptan, a nonyl mercaptan, a decyl mercaptan, a dodecyl mercaptan, a tetradecane mercaptan, a cetyl mercaptan, and a stearyl mercaptan, etc. Specifically, the organic phosphoric acid with a carbon number of eight or more includes one or more of a dodecylphosphonic acid, a tetradecylphosphoric acid, a hexadecylphosphoric acid, and an octadecylphosphoric acid, etc. Specifically, the primary amine with a carbon number of eight or more includes one or more of an octylamine, a nonylamine, a decylamine, a dodecylamine, a tetradecylamine, a hexadecylamine, and an octadecylamine, etc.

Further, in some embodiments, the secondary or tertiary amine having a side chain with a carbon number of four or more includes one or more of a dibutylamine, a dihexylamine, a diheptylamine, a dioctylamine, a dinonylamine, a didecylamine, a tributyl, a trihexylamine, a triheptylamine, a trioctylamine, a trinonylamine, and a tridecylamine, etc.

Further, in some embodiments, the substituted or unsubstituted alkylaminophosphine includes one or more of a tri (dimethylamino) phosphine, a tri (diethylamino) phosphine, a tri (dipropylamino) phosphine, a tri (dibutylamino) phosphine, a tri (dipentylamino) phosphine, a tri (dihexylamino) phosphine, a tri (diheptylamino) phosphine, a tri (dioctylamino) phosphine, and a dibenzyldiethylaminophosphine, but not limited thereto.

Further, in some embodiments, the substituted or unsubstituted alkoxyphosphine includes one or more of a tributylphosphine oxide, a tripentylphosphine oxide, a trihexylphosphine oxide, a triheptylphosphine oxide, a trioctylphosphine oxide, a trinonylphosphine oxide, a tridecylphosphine oxide, a diphenylmethoxyphosphine, a diphenylethoxyphosphine, a diphenylpropoxyphosphine, a diphenylbutoxyphosphine, a dimethylphenylphosphine oxide, a diethylphenyloxyphosphine oxide, a dipropylphenylphosphine oxide, a dibutylphenylphosphine oxide, a methyldiphenylphosphine oxide, a ethyldiphenylphosphine oxide, a propyldiphenylphosphine oxide, a butyldiphenylphosphine oxide, and a chloro (diisopropylamino) methoxyphosphorus, but not limited thereto.

Further, in some embodiments, the substituted or unsubstituted silylphosphine includes one or more of a tris (trisilyl) phosphine, a tri (triethylsilyl) phosphine, a tri (tripropylsilyl) phosphine, a tri (tributylsilyl) phosphine, a tri (trispentasilyl) phosphine, a tri (trihexylsilyl) phosphine, a tri (triheptylsilyl) phosphine, and a tri (trioctylsilyl) phosphine, but not limited thereto.

Further, in some embodiments, the alkylphosphine having a side chain with a carbon number of four or more includes one or more of a tributylphosphine, a triheptylphosphine, and a trioctylphosphine, but not limited thereto.

In a specific embodiment, the oil-soluble organic ligand includes one or more of a thiol with a carbon number of eight or more, an organic phosphoric acid with a carbon number of eight or more, and a substituted or unsubstituted alkylaminophosphine. The organic phosphoric acid is bonded to cations on the surface of the inorganic semiconductor nanocrystal by an ionic bond. The thiol is bonded to cations on the surface of the inorganic semiconductor nanocrystal by a hydrogen bond. The alkylaminophosphine is bonded to cations on the surface of the inorganic semiconductor nanocrystal by a lone electron pair of P and a hydrogen bond in —NH₂ simultaneously. These bonds are strong and hence the oil-soluble organic ligand is not easy to fall off, thereby ensuring the solubility and transportability of the composite material. Further, these types of ligands are not bonded to surface ions of the inorganic semiconductor nanocrystal through a —OH, and hence will not undergo hydrolysis.

In a specific embodiment, the oil-soluble organic ligand is a substituted or unsubstituted alkylaminophosphine, and the particle is a metal sulfide particle. The substituted or unsubstituted alkylaminophosphine is bonded to cations on the surface of the particle by a lone electron pair of P and a hydrogen bond in —NH₂ simultaneously. Since an ionic bond of the halogen ligand is strong, the bond between the alkylaminophosphine and the surface of the particle is strong and the oil-soluble organic ligand is not easy to fall off. In addition, when the alkylaminophosphine and the iodine ligand are bonded to the metal sulfide particle, no —OH is bonded to the surface of the metal sulfide particle, which will not cause hydrolysis or oxidation of the metal sulfide particle.

In a specific embodiment, the oil-soluble organic ligand is an organic phosphoric acid with a carbon number of eight or more, and the particle is a metal oxide particle. The organic phosphoric acid is bonded to the metal oxide particle by an ionic bond that is relatively strong. The metal oxide particle is not directly bonded with —OH, and hence is not easy to hydrolyze and deteriorate.

In a specific embodiment, the oil-soluble organic ligand is a thiol with a carbon number of eight or more, and the particle is a metal sulfide particle. The thiol is bonded to cations on the surface of the metal sulfide particle by a hydrogen bond that is relatively strong and not easy to fall off. In addition, when the thiol is bonded to the metal sulfide particle, no —OH is bonded to the surface of the metal sulfide particle, which will not cause hydrolysis or oxidation of the metal sulfide particle.

In some embodiments, the inorganic semiconductor nanocrystal includes a doped metal element. The presence of the oil-soluble organic ligand can relatively greatly reduce the electron transport performance. On the other hand, doping with the metal element can reduce the injection barrier of the electron transport layer to the light-emitting layer or form excess free electrons, which can improve the electron transport performance to a certain extent. As such, the electron transport rate and hole transport rate in the device can be further adjusted and the light-emitting efficiency of the light-emitting layer can be further improved.

Further, in some embodiments, the doped metal element accounts for 0.5-10% of the inorganic semiconductor nanocrystal in terms of mass percentage.

Further, in some embodiments, the doped metal element includes one or more of Mg, Mn, Al, Y, V, and Ni.

Further, in some embodiments, the inorganic semiconductor nanocrystal includes a ZnO particle, a ZnS particle, or a SnO particle, and the doped metal element is Al, V, or Y. The HOMO energy levels of these inorganic semiconductor nanocrystals can better match the HOMO energy levels of the quantum dots in the light-emitting layer. Doping ions can reduce the injection barrier of the electron transport layer to the light-emitting layer, thereby ensuring the effectiveness of the electron transport between the materials of the transport layer and the light-emitting layer. Specifically, the doped metal element is Y.

An embodiment of the present disclosure provides a method for preparing a composite material including the following processes.

A cationic precursor and a first oil-soluble organic ligand are dispersed into a solvent and heated at a first temperature to obtain a first mixture, where the cationic precursor is a metal halide.

An anionic precursor is dispersed into a solvent and heated at a second temperature to obtain a second mixture, where the anionic precursor is an organic alcohol.

The first mixture is heated at a third temperature, and the second mixture is injected during the heating process for a crystal growth of an inorganic semiconductor nanocrystal to obtain a composite material, where the third temperature is higher than the first temperature and the second temperature.

In this embodiment, the organic alcohol is used as the anionic precursor. The cationic precursor containing a halogen undergoes an alcoholysis reaction with the organic alcohol at high temperature to obtain a metal oxide semiconductor nanocrystal. The halogen ion in the cationic precursor containing the halogen and the first oil-soluble organic ligand are bound on the surface of the metal oxide semiconductor nanocrystal. The composite material obtained by the reaction of this method has small and uniform size and fewer surface defects. Further, the composite material has no emission peak in the visible band, and does not interfere with the emission of the light-emitting layer in a device structure. The metal oxide semiconductor nanocrystal has the following mixed ligands on the surface thereof: the halogen ligand and the first oil-soluble organic ligand that makes the composite material oil-soluble. In the composite material, the halogen ligand can improve the electron transport performance, and the oil-soluble organic ligand can effectively reduce the electron transport rate, so that the electron transport performance of the material may be adjusted, thereby adjusting the electron transport rate and the hole transport rate in the device, and hence improving the light-emitting efficiency of the light-emitting layer.

In some embodiments, the metal halide includes one or more of chloride, bromide, and iodide of zinc element; or one or more of chloride, bromide, and iodide of cadmium element; or one or more of chloride, bromide, and iodide of tin element; or one or more of chloride, bromide, and iodide of germanium element. For example, the metal halide can include one or more of ZnCl₂, ZnBr₂, and ZnI₂; or one or more of CdCl₂, CdBr₂ and CdI₂; or one or more of SnCl₂, SnBr₂ and SnI₂; or one or more of GeCl₂, GeBr₂, and GeI₂, etc.

Further, in some embodiments, the metal halide includes ZnCl₂, CdCl₂, SnCl₂, GeCl₂, etc. Since the atomic radius of chlorine is small compared to bromine and iodine, when it is used as a surface ligand on the surface of the particle, the distance that an electron needs to travel during transport is small, which can improve the electron transportability.

In some embodiments, the first oil-soluble organic ligand includes one or more of an organic carboxylic acid with a carbon number of eight or more, an organic phosphoric acid with a carbon number of eight or more, a primary amine with a carbon number of eight or more, and a secondary or tertiary amine having a side chain with a carbon number of four or more.

Further, in some embodiments, the first oil-soluble organic ligand is an organic phosphoric acid with a carbon number of eight or more. The organic phosphoric acid is bonded to the metal oxide particle by an ionic bond that is relatively strong. The metal oxide particle is not directly bonded with —OH, and hence is not easy to hydrolyze and deteriorate.

In some embodiments, the organic alcohol includes one or more of octanol, nonanol, decanol, undecanol, dodecanol, tridecanol, tetradecanol, pentadecyl alcohol, hexadecanol, heptadecyl alcohol, and stearyl alcohol.

In some embodiments, the first temperature is 110-190° C.

In some embodiments, the second temperature is 110-190° C.

In this embodiment, the prepared inorganic semiconductor nanocrystal is a metal oxide particle selected from a ZnO particle, a CdO particle, a SnO particle, or a GeO particle, but not limited thereto. At a small particle size (2-7 nm), the inorganic semiconductor nanocrystal mainly emits light through defect states. On the other hand, in the method of this embodiment, nucleation occurs at a relatively high temperature (i.e., the third temperature), and by controlling the particle size, the prepared inorganic semiconductor nanocrystal has fewer surface defects and may realize no emission peak in the visible band. The third temperature is 210-350° C. In some embodiments, the third temperature is 230-300° C.

In some embodiments, the first mixture is heated at the third temperature, and the second mixture is injected during the heating process for a crystal growth of an inorganic semiconductor nanocrystal. After the crystal growth is completed, a third oil-soluble organic ligand is added during the cooling process, so that the third oil-soluble organic ligand is bound on the surface of the semiconductor nanocrystal to obtain a composite material. The third oil-soluble organic ligand is a thiol with a carbon number of eight or more. The third temperature is higher than the first temperature and the second temperature.

In some embodiments, the first mixture further includes a doped metal salt. The presence of the oil-soluble organic ligand can relatively greatly reduce the electron transport performance. On the other hand, doping with the metal element can reduce the injection barrier of the electron transport layer to the light-emitting layer or form excess free electrons, which can improve the electron transport performance to a certain extent. As such, the electron transport rate and hole transport rate in the device can be further adjusted and the light-emitting efficiency of the light-emitting layer can be further improved.

Further, in some embodiments, the doped metal element accounts for 0.5-10% of the inorganic semiconductor nanocrystal in terms of mass percentage.

Further, in some embodiments, the doped metal element includes one or more of Mg, Mn, Al, Y, V, and Ni.

Further, in some embodiments, the inorganic semiconductor nanocrystal includes a ZnO particle, a ZnS particle, or a SnO particle, and the doped metal element is Al, V, or Y. The HOMO energy levels of these inorganic semiconductor nanocrystals can better match the HOMO energy levels of the quantum dots in the light-emitting layer. Doping ions can reduce the injection barrier of the electron transport layer to the light-emitting layer, thereby ensuring the effectiveness of the electron transport between the materials of the transport layer and the light-emitting layer. Specifically, the doped metal element is Y.

An embodiment of the present disclosure provides a method for preparing a composite material including the following processes.

A cationic precursor is dispersed into a solvent and heated at a first temperature to obtain a first mixture, where the cationic precursor is a metal halide.

An anionic precursor and a second oil-soluble organic ligand are dispersed into a solvent and heated at a second temperature to obtain a second mixture, where the anionic precursor is an organic alcohol.

The first mixture is heated at a third temperature, and the second mixture is injected during the heating process for a crystal growth of an inorganic semiconductor nanocrystal to obtain a composite material, where the third temperature is higher than the first temperature and the second temperature.

In this embodiment, the organic alcohol is used as the anionic precursor. The cationic precursor containing a halogen undergoes an alcoholysis reaction with the organic alcohol at high temperature to obtain a metal oxide semiconductor nanocrystal. The halogen ion in the cationic precursor containing the halogen and the second oil-soluble organic ligand are bound on the surface of the metal oxide semiconductor nanocrystal. The composite material obtained by the reaction of this method has small and uniform size and fewer surface defects. Further, the composite material has no emission peak in the visible band, and does not interfere with the emission of the light-emitting layer in a device structure. The metal oxide semiconductor nanocrystal has the following mixed ligands on the surface thereof: the halogen ligand and the second oil-soluble organic ligand that makes the composite material oil-soluble. In the composite material, the halogen ligand can improve the electron transport performance, and the oil-soluble organic ligand can effectively reduce the electron transport rate, so that the electron transport performance of the material may be adjusted, thereby adjusting the electron transport rate and the hole transport rate in the device, and hence improving the light-emitting efficiency of the light-emitting layer.

In some embodiments, the metal halide includes one or more of chloride, bromide, and iodide of zinc element; or one or more of chloride, bromide, and iodide of cadmium element; or one or more of chloride, bromide, and iodide of tin element; or one or more of chloride, bromide, and iodide of germanium element. For example, the metal halide can include one or more of ZnCl₂, ZnBr₂, and ZnI₂; or one or more of CdCl₂, CdBr₂ and CdI₂; or one or more of SnCl₂, SnBr₂ and SnI₂; or one or more of GeCl₂, GeBr₂, and GeI₂, etc.

Further, in some embodiments, the metal halide includes ZnCl₂, CdCl₂, SnCl₂, GeCl₂, etc. Since the atomic radius of chlorine is small compared to bromine and iodine, when the surface of the particle is used as a surface ligand, the distance that electron needs to travel during transport is small, which can improve the electron transportability.

In some embodiments, the second oil-soluble organic ligand includes one or more of a substituted or unsubstituted alkylaminophosphine, a substituted or unsubstituted alkoxyphosphine, a substituted or unsubstituted silylphosphine, and an alkylphosphine having a side chain with a carbon number of four or more.

In some embodiments, the organic alcohol includes one or more of octanol, nonanol, decanol, undecanol, dodecanol, tridecanol, tetradecanol, pentadecyl alcohol, hexadecanol, heptadecyl alcohol, and stearyl alcohol.

In some embodiments, the first temperature is 110-190° C.

In some embodiments, the second temperature is 110-190° C.

In this embodiment, the prepared inorganic semiconductor nanocrystal is a metal oxide particle selected from a ZnO particle, a CdO particle, a SnO particle, or a GeO particle, but not limited thereto. At a small particle size (2-7 nm), the inorganic semiconductor nanocrystal mainly emits light through defect states. On the other hand, in the method of this embodiment, nucleation occurs at a relatively high temperature (i.e., the third temperature), and by controlling the particle size, the prepared inorganic semiconductor nanocrystal has fewer surface defects and may realize no emission peak in the visible band, and can be used as an electron transport material. The third temperature is 210-350° C. In some embodiments, the third temperature is 230-300° C.

In some embodiments, the first mixture is heated at the third temperature, and the second mixture is injected during the heating process for a crystal growth of an inorganic semiconductor nanocrystal. After the crystal growth is completed, a third oil-soluble organic ligand is added during the cooling process, so that the third oil-soluble organic ligand is bound on the surface of the semiconductor nanocrystal to obtain a composite material. The third oil-soluble organic ligand is thiol with a carbon number of eight or more. The third temperature is higher than the first temperature and the second temperature.

In some embodiments, the first mixture further includes a doped metal salt. The presence of the oil-soluble organic ligand can relatively greatly reduce the electron transport performance. On the other hand, doping with the metal element can reduce the injection barrier of the electron transport layer to the light-emitting layer or form excess free electrons, which can improve the electron transport performance to a certain extent. As such, the electron transport rate and hole transport rate in the device can be further adjusted and the light-emitting efficiency of the light-emitting layer can be further improved.

Further, in some embodiments, the doped metal element accounts for 0.5-10% of the inorganic semiconductor nanocrystal in terms of mass percentage.

Further, in some embodiments, the doped metal element includes one or more of Mg, Mn, Al, Y, V, and Ni.

Further, in some embodiments, the inorganic semiconductor nanocrystal includes a ZnO particle, a ZnS particle, or a SnO particle, and the doped metal element is Al, V, or Y. The HOMO energy levels of these inorganic semiconductor nanocrystals can better match the HOMO energy levels of the quantum dots in the light-emitting layer. Doping ions can reduce the injection barrier of the electron transport layer to the light-emitting layer, thereby ensuring the effectiveness of the electron transport between the materials of the transport layer and the light-emitting layer. Specifically, the doped metal element is Y.

An embodiment of the present disclosure provides a method for preparing a composite material including the following processes.

A cationic precursor and a first oil-soluble organic ligand are dispersed into a solvent and heated at a first temperature to obtain a first mixture, where the cationic precursor is a metal halide.

An anionic precursor and a second oil-soluble organic ligand are dispersed into a solvent and heated at a second temperature to obtain a second mixture, where the anionic precursor is an organic alcohol.

The first mixture is heated at a third temperature, and the second mixture is injected during the heating process for a crystal growth of an inorganic semiconductor nanocrystal to obtain a composite material, where the third temperature is higher than the first temperature and the second temperature.

In this embodiment, the organic alcohol is used as the anionic precursor. The cationic precursor containing a halogen undergoes an alcoholysis reaction with the organic alcohol at high temperature to obtain a metal oxide semiconductor nanocrystal. The halogen ion in the cationic precursor containing the halogen, the first oil-soluble organic ligand, and the second oil-soluble organic ligand are bound on the surface of the metal oxide semiconductor nanocrystal. The composite material obtained by the reaction of this method has small and uniform size and fewer surface defects. Further, the composite material has no emission peak in the visible band, and does not interfere with the emission of the light-emitting layer in a device structure. The metal oxide semiconductor nanocrystal has the following mixed ligands on the surface thereof: the halogen ligand, the first oil-soluble organic ligand and the second oil-soluble organic ligand that make the composite material oil-soluble. In the composite material, the halogen ligand can improve the electron transport performance, and the oil-soluble organic ligand can effectively reduce the electron transport rate, so that the electron transport performance of the material may be adjusted, thereby adjusting the electron transport rate and the hole transport rate in the device, and hence improving the light-emitting efficiency of the light-emitting layer.

In some embodiments, the metal halide includes one or more of chloride, bromide, and iodide of zinc element; or one or more of chloride, bromide, and iodide of cadmium element; or one or more of chloride, bromide, and iodide of tin element; or one or more of chloride, bromide, and iodide of germanium element. For example, the metal halide can include one or more of ZnCl₂, ZnBr₂, and ZnI₂; or one or more of CdCl₂, CdBr₂ and CdI₂; or one or more of SnCl₂, SnBr₂ and SnI₂; or one or more of GeCl₂, GeBr₂, and GeI₂, etc.

Further, in some embodiments, the metal halide includes ZnCl₂, CdCl₂, SnCl₂, GeCl₂, etc. Since the atomic radius of chlorine is small compared to bromine and iodine, when it is used as a surface ligand on the surface of the particle, the distance that an electron needs to travel during transport is small, which can improve the electron transportability.

In some embodiments, the first oil-soluble organic ligand includes one or more of an organic carboxylic acid with a carbon number of eight or more, an organic phosphoric acid with a carbon number of eight or more, a primary amine with a carbon number of eight or more, and a secondary or tertiary amine having a side chain with a carbon number of four or more; and/or the second oil-soluble organic ligand includes one or more of a substituted or unsubstituted alkylaminophosphine, a substituted or unsubstituted alkoxyphosphine, a substituted or unsubstituted silylphosphine, and an alkylphosphine having a side chain with a carbon number of four or more.

Further, in some embodiments, the first oil-soluble organic ligand is an organic phosphoric acid with a carbon number of eight or more, and the second oil-soluble organic ligand is a substituted or unsubstituted alkylaminophosphine. The organic phosphoric acid is bonded to cations on the surface of the inorganic semiconductor nanocrystal by an ionic bond. The alkylaminophosphine is bonded to cations on the surface of the inorganic semiconductor nanocrystal by a lone electron pair of P and a hydrogen bond in —NH₂ simultaneously. These two bonds are strong and hence the oil-soluble organic ligand is not easy to fall off, thereby ensuring the solubility and transportability of the composite material. Further, these two types of ligands are not bonded to surface ions of the inorganic semiconductor nanocrystal through a —OH, and hence will not undergo hydrolysis.

In some embodiments, the organic alcohol includes one or more of an octanol, a nonanol, a decanol, an undecanol, a dodecanol, a tridecanol, a tetradecanol, a pentadecyl alcohol, a hexadecanol, a heptadecyl alcohol, and a stearyl alcohol.

In some embodiments, the first temperature is 110-190° C.

In some embodiments, the second temperature is 110-190° C.

In this embodiment, the prepared inorganic semiconductor nanocrystal is a metal oxide particle selected from a ZnO particle, a CdO particle, a SnO particle, or a GeO particle, but not limited thereto. At a small particle size (2-7 nm), the inorganic semiconductor nanocrystal mainly emits light through defect states. On the other hand, in the method of this embodiment, nucleation occurs at a relatively high temperature (i.e., the third temperature), and by controlling the particle size, the prepared inorganic semiconductor nanocrystal has fewer surface defects and may realize no emission peak in the visible band. The third temperature is 210-350° C. In some embodiments, the third temperature is 230-300° C.

In some embodiments, the first mixture is heated at the third temperature, and the second mixture is injected during the heating process for a crystal growth of an inorganic semiconductor nanocrystal. After the crystal growth is completed, a third oil-soluble organic ligand is added during the cooling process, so that the third oil-soluble organic ligand is bound on the surface of the semiconductor nanocrystal to obtain a composite material. The third oil-soluble organic ligand is thiol with a carbon number of eight or more. The third temperature is higher than the first temperature and the second temperature. In this embodiment, the organic alcohol is used as the anionic precursor. The cationic precursor containing a halogen undergoes an alcoholysis reaction with the organic alcohol at high temperature to obtain a metal oxide semiconductor nanocrystal. The halogen ion in the cationic precursor containing the halogen, the first oil-soluble organic ligand, the second oil-soluble organic ligand, and the third oil-soluble organic ligand are bound on the surface of the metal oxide semiconductor nanocrystal.

Further, in some embodiments, the first oil-soluble organic ligand is an organic phosphoric acid with a carbon number of eight or more, the second oil-soluble organic ligand is a substituted or unsubstituted alkylaminophosphine, and the third oil-soluble organic ligand is a thiol with a carbon number of eight or more. The organic phosphoric acid is bonded to cations on the surface of the inorganic semiconductor nanocrystal by an ionic bond. The thiol is bonded to cations on the surface of the inorganic semiconductor nanocrystal by a hydrogen bond. The alkylaminophosphine is bonded to cations on the surface of the inorganic semiconductor nanocrystal by a lone electron pair of P and a hydrogen bond in —NH₂ simultaneously. These bonds are strong and hence the oil-soluble organic ligand is not easy to fall off, thereby ensuring the solubility and transportability of the composite material. Further, these types of ligands are not bonded to surface ions of the inorganic semiconductor nanocrystal through a —OH, and hence will not undergo hydrolysis.

In some embodiments, the first mixture further includes a doped metal salt. The presence of the oil-soluble organic ligand can relatively greatly reduce the electron transport performance. On the other hand, doping with the metal element can reduce the injection barrier of the electron transport layer to the light-emitting layer or form excess free electrons, which can improve the electron transport performance to a certain extent. As such, the electron transport rate and hole transport rate in the device can be further adjusted and the light-emitting efficiency of the light-emitting layer can be further improved.

Further, in some embodiments, the doped metal element accounts for 0.5-10% of the inorganic semiconductor nanocrystal in terms of mass percentage.

Further, in some embodiments, the doped metal element includes one or more of Mg, Mn, Al, Y, V, and Ni.

Further, in some embodiments, the inorganic semiconductor nanocrystal includes a ZnO particle, a ZnS particle, or a SnO particle, and the doped metal element is Al, V, or Y. The HOMO energy levels of these inorganic semiconductor nanocrystals can better match the HOMO energy levels of the quantum dots in the light-emitting layer. Doping ions can reduce the injection barrier of the electron transport layer to the light-emitting layer, thereby ensuring the effectiveness of the electron transport between the materials of the transport layer and the light-emitting layer. Specifically, the doped metal element is Y.

An embodiment of the present disclosure provides a method for preparing a composite material including the following processes.

A cationic precursor is dispersed into a solvent and heated at a first temperature to obtain a first mixture, where the cationic precursor is a metal halide.

An anionic precursor is dispersed into a solvent and heated at a second temperature to obtain a second mixture, where the anionic precursor is an organic alcohol.

The first mixture is heated at a third temperature, and the second mixture is injected during the heating process for a crystal growth of an inorganic semiconductor nanocrystal. After the crystal growth is completed, a third oil-soluble organic ligand is added during the cooling process, so that the third oil-soluble organic ligand is bound on the surface of the semiconductor nanocrystal to obtain a composite material. The third oil-soluble organic ligand is a thiol with a carbon number of eight or more. The third temperature is higher than the first temperature and the second temperature.

In this embodiment, the organic alcohol is used as the anionic precursor. The cationic precursor containing a halogen undergoes an alcoholysis reaction with the organic alcohol at high temperature to obtain a metal oxide semiconductor nanocrystal. The halogen ion in the cationic precursor containing the halogen, and the third oil-soluble organic ligand are bound on the surface of the metal oxide semiconductor nanocrystal. The composite material obtained by the reaction of this method has small and uniform size and fewer surface defects. Further, the composite material has no emission peak in the visible band, and does not interfere with the emission of the light-emitting layer in a device structure. The metal oxide semiconductor nanocrystal has the following mixed ligands on the surface thereof: the halogen ligand and the third oil-soluble organic ligand that makes the composite material oil-soluble. In the composite material, the halogen ligand can improve the electron transport performance, and the oil-soluble organic ligand can effectively reduce the electron transport rate, so that the electron transport performance of the material may be adjusted, thereby adjusting the electron transport rate and the hole transport rate in the device, and hence improving the light-emitting efficiency of the light-emitting layer.

In some embodiments, the metal halide includes one or more of chloride, bromide, and iodide of zinc element; or one or more of chloride, bromide, and iodide of cadmium element; or one or more of chloride, bromide, and iodide of tin element; or one or more of chloride, bromide, and iodide of germanium element. For example, the metal halide can include one or more of ZnCl₂, ZnBr₂, and ZnI₂; or one or more of CdCl₂, CdBr₂ and CdI₂; or one or more of SnCl₂, SnBr₂ and SnI₂; or one or more of GeCl₂, GeBr₂, and GeI₂, etc.

Further, in some embodiments, the metal halide includes ZnCl₂, CdCl₂, SnCl₂, GeCl₂, etc. Since the atomic radius of chlorine is small compared to bromine and iodine, when it is used as a surface ligand on the surface of the particle, the distance that an electron needs to travel during transport is small, which can improve the electron transportability.

In some embodiments, the organic alcohol includes one or more of an octanol, a nonanol, a decanol, an undecanol, a dodecanol, a tridecanol, a tetradecanol, a pentadecyl alcohol, a hexadecanol, a heptadecyl alcohol, and a stearyl alcohol.

In some embodiments, the first temperature is 110-190° C.

In some embodiments, the second temperature is 110-190° C.

In this embodiment, the prepared inorganic semiconductor nanocrystal is a metal oxide particle selected from a ZnO particle, a CdO particle, a SnO particle, or a GeO particle, but not limited thereto. At a small particle size (2-7 nm), the inorganic semiconductor nanocrystal mainly emits light through defect states. On the other hand, in the method of this embodiment, nucleation occurs at a relatively high temperature (i.e., the third temperature), and by controlling the particle size, the prepared inorganic semiconductor nanocrystal has fewer surface defects and may realize no emission peak in the visible band. The third temperature is 210-350° C. In some embodiments, the third temperature is 230-300° C.

In some embodiments, the first mixture further includes a doped metal salt. The presence of the oil-soluble organic ligand can relatively greatly reduce the electron transport performance. On the other hand, doping with the metal element can reduce the injection barrier of the electron transport layer to the light-emitting layer or form excess free electrons, which can improve the electron transport performance to a certain extent. As such, the electron transport rate and hole transport rate in the device can be further adjusted and the light-emitting efficiency of the light-emitting layer can be further improved.

Further, in some embodiments, the doped metal element accounts for 0.5-10% of the inorganic semiconductor nanocrystal in terms of mass percentage.

Further, in some embodiments, the doped metal element includes one or more of Mg, Mn, Al, Y, V, and Ni.

Further, in some embodiments, the inorganic semiconductor nanocrystal includes a ZnO particle, a ZnS particle, or a SnO particle, and the doped metal element is Al, V, or Y. The HOMO energy levels of these inorganic semiconductor nanocrystals can better match the HOMO energy levels of the quantum dots in the light-emitting layer. Doping ions can reduce the injection barrier of the electron transport layer to the light-emitting layer, thereby ensuring the effectiveness of the electron transport between the materials of the transport layer and the light-emitting layer. Specifically, the doped metal element is Y.

An embodiment of the present disclosure provides a method for preparing a composite material including the following processes.

A cationic precursor and a first oil-soluble organic ligand are dispersed into a solvent and heated at a first temperature to obtain a first mixture, where the cationic precursor is a metal halide.

An anionic precursor is dispersed into a solvent and heated at a second temperature to obtain a second mixture, where the anionic precursor is a thiol with a carbon number of eight or more and/or a sulfur element.

The first mixture is heated at a third temperature, and the second mixture is injected during the heating process for a crystal growth of a semiconductor nanocrystal to obtain a composite material, where the third temperature is higher than the first temperature and the second temperature.

In this embodiment, the cationic precursor containing a halogen reacts with the anionic precursor containing a sulfur at high temperature to obtain a metal sulfide semiconductor nanocrystal. The halogen ion in the cationic precursor containing the halogen and the first oil-soluble organic ligand are bound on the surface of the metal sulfide semiconductor nanocrystal. The composite material obtained by the reaction at high temperature has small and uniform size and fewer surface defects. Further, the composite material has no emission peak in the visible band, and does not interfere with the emission of the light-emitting layer in a device structure. The metal sulfide semiconductor nanocrystal has the following mixed ligands on the surface thereof: the halogen ligand and the first oil-soluble organic ligand that makes the composite material oil-soluble. In the composite material, the halogen ligand can improve the electron transport performance, and the oil-soluble organic ligand can effectively reduce the electron transport rate, so that the electron transport performance of the material may be adjusted, thereby adjusting the electron transport rate and the hole transport rate in the device, and hence improving the light-emitting efficiency of the light-emitting layer.

In some embodiments, the anionic precursor is a thiol with a carbon number of eight or more. The cationic precursor containing a halogen undergoes an alcoholysis reaction with the thiol at high temperature to obtain a metal sulfide semiconductor nanocrystal. The halogen ion in the cationic precursor containing the halogen, and the first oil-soluble organic ligand are bound on the surface of the metal sulfide semiconductor nanocrystal. In addition, excess thiol can also be bound on the surface of the metal sulfide semiconductor nanocrystal as surface ligands. When the amount of thiol added is greater than the amount needed for nucleation of the metal sulfide semiconductor nanocrystal growth, it is indicated that the thiol is excessive.

In some embodiments, the anionic precursor is a sulfur element that is added in a form of sulfur-non-coordinating solvent after mixing with a non-coordinating solvent. The sulfur element is dispersed in the non-coordinating solvent to form a uniform liquid, which is convenient for a subsequent injection. The cationic precursor containing a halogen reacts with the sulfur element at high temperature to obtain a metal sulfide semiconductor nanocrystal. The halogen ion in the cationic precursor containing the halogen and the first oil-soluble organic ligand are bound on the surface of the metal sulfide semiconductor nanocrystal. It should be noted that the non-coordinating solvent can be used as a ligand to be bound on the surface of the metal sulfide semiconductor nanocrystal in addition to dispersing the sulfur element.

In some embodiments, the sulfur-non-coordinating solvent includes one or more of a sulfur-dodecene, a sulfur-tetradecene, a sulfur-hexadecene, a sulfur-octadecene, a sulfur-tributylphosphine, a sulfur-triheptylphosphine, a sulfur-trioctylphosphine, a sulfur-tri (dimethylamino) phosphine, a sulfur-tri (diethylamino) phosphine, a sulfur-tri (trimethylsilyl) phosphine, a sulfur-dibenzyldiethylaminophosphine and a sulfur-(diisopropylamino) methoxyphosphine, etc.

In some embodiments, the anionic precursor is a thiol with a carbon number of eight or more and a sulfur element, where the sulfur element is added in a form of sulfur-non-coordinating solvent after mixing with a non-coordinating solvent. The sulfur element is dispersed in the non-coordinating solvent to form a uniform liquid, which is convenient for a subsequent injection. The cationic precursor containing a halogen reacts with the thiol and the sulfur element at high temperature to obtain a metal sulfide semiconductor nanocrystal. The halogen ion in the cationic precursor containing the halogen and the first oil-soluble organic ligand are bound on the surface of the metal sulfide semiconductor nanocrystal. In addition, excess thiol can also be bound on the surface of the metal sulfide semiconductor nanocrystal as surface ligands. When the amount of thiol added is greater than the amount needed for nucleation of the metal sulfide semiconductor nanocrystal growth, it is indicated that the thiol is excessive. It should be noted that the non-coordinating solvent can be used as a ligand to be bound on the surface of the metal sulfide semiconductor nanocrystal in addition to dispersing the sulfur element.

In some embodiments, the sulfur-non-coordinating solvent includes one or more of a sulfur-dodecene, a sulfur-tetradecene, a sulfur-hexadecene, a sulfur-octadecene, a sulfur-tributylphosphine, a sulfur-triheptylphosphine, a sulfur-trioctylphosphine, a sulfur-tri (dimethylamino) phosphine, a sulfur-tri (diethylamino) phosphine, a sulfur-tri (trimethylsilyl) phosphine, a sulfur-dibenzyldiethylaminophosphine and a sulfur-(diisopropylamino) methoxyphosphine, etc.

In some embodiments, the thiol with a carbon number of eight or more includes one or more of an octanethiol, a nonanethiol, a decanethiol, an undecanethiol, a dodecanethiol, a tridecanethiol, a tetradecanethiol, a pentadecylthiol, a hexadecanethiol, a heptadecanethiol and an octadecanethiol.

In some embodiments, the metal halide includes one or more of chloride, bromide, and iodide of zinc element; or one or more of chloride, bromide, and iodide of tin element; or one or more of chloride, bromide, and iodide of germanium element. For example, the metal halide can include one or more of ZnCl₂, ZnBr₂, and ZnI₂; or one or more of SnCl₂, SnBr₂ and SnI₂; or one or more of GeCl₂, GeBr₂, and GeI₂, etc.

Further, in some embodiments, the metal halide includes ZnCl₂, SnCl₂, GeCl₂, etc. Since the atomic radius of chlorine is small compared to bromine and iodine, when it is used as a surface ligand on the surface of the particle, the distance that an electron needs to travel during transport is small, which can improve the electron transportability.

In some embodiments, the first oil-soluble organic ligand includes one or more of an organic carboxylic acid with a carbon number of eight or more, an organic phosphoric acid with a carbon number of eight or more, a primary amine with a carbon number of eight or more, and a secondary or tertiary amine having a side chain with a carbon number of four or more.

In some embodiments, the first temperature is 110-190° C.

In some embodiments, the second temperature is 110-190° C.

In this embodiment, the prepared inorganic semiconductor nanocrystal is a metal sulfide particle selected from a ZnS particle, a SnS particle, or a GeS particle, but not limited thereto. At a small particle size (2-7 nm), the inorganic semiconductor nanocrystal mainly emits light through defect states. On the other hand, in the method of this embodiment, nucleation occurs at a relatively high temperature (i.e., the third temperature), and by controlling the particle size, the prepared inorganic semiconductor nanocrystal has fewer surface defects and may realize no emission peak in the visible band. The third temperature is 210-350° C. In some embodiments, the third temperature is 230-300° C.

In some embodiments, the first mixture further includes a doped metal salt. The presence of the oil-soluble organic ligand can relatively greatly reduce the electron transport performance. On the other hand, doping with the metal element can reduce the injection barrier of the electron transport layer to the light-emitting layer or form excess free electrons, which can improve the electron transport performance to a certain extent. As such, the electron transport rate and hole transport rate in the device can be further adjusted and the light-emitting efficiency of the light-emitting layer can be further improved.

Further, in some embodiments, the doped metal element accounts for 0.5-10% of the inorganic semiconductor nanocrystal in terms of mass percentage.

Further, in some embodiments, the doped metal element includes one or more of Mg, Mn, Al, Y, V, and Ni.

Further, in some embodiments, the inorganic semiconductor nanocrystal includes a ZnO particle, a ZnS particle, or a SnO particle, and the doped metal element is Al, V, or Y. The HOMO energy levels of these inorganic semiconductor nanocrystals can better match the HOMO energy levels of the quantum dots in the light-emitting layer. Doping ions can reduce the injection barrier of the electron transport layer to the light-emitting layer, thereby ensuring the effectiveness of the electron transport between the materials of the transport layer and the light-emitting layer. Specifically, the doped metal element is Y.

An embodiment of the present disclosure provides a method for preparing a composite material including the following processes.

A cationic precursor is dispersed into a solvent and heated at a first temperature to obtain a first mixture, where the cationic precursor is a metal halide.

An anionic precursor and a second oil-soluble organic ligand are dispersed into a solvent and heated at a second temperature to obtain a second mixture, where the anionic precursor is a thiol with a carbon number of eight or more and/or a sulfur element.

The first mixture is heated at a third temperature, and the second mixture is injected during the heating process for a crystal growth of a semiconductor nanocrystal to obtain a composite material, where the third temperature is higher than the first temperature and the second temperature.

In this embodiment, the cationic precursor containing a halogen reacts with the anionic precursor containing a sulfur at high temperature to obtain a metal sulfide semiconductor nanocrystal. The halogen ion in the cationic precursor containing the halogen and the second oil-soluble organic ligand are bound on the surface of the metal sulfide semiconductor nanocrystal. The composite material obtained by the reaction at high temperature has small and uniform size and fewer surface defects. Further, the composite material has no emission peak in the visible band, and does not interfere with the emission of the light-emitting layer in a device structure. The metal sulfide semiconductor nanocrystal has the following mixed ligands on the surface thereof: the halogen ligand and the second oil-soluble organic ligand that makes the composite material oil-soluble. In the composite material, the halogen ligand can improve the electron transport performance, and the oil-soluble organic ligand can effectively reduce the electron transport rate, so that the electron transport performance of the material may be adjusted, thereby adjusting the electron transport rate and the hole transport rate in the device, and hence improving the light-emitting efficiency of the light-emitting layer.

In some embodiments, the anionic precursor is a thiol with a carbon number of eight or more. The cationic precursor containing a halogen undergoes an alcoholysis reaction with the thiol at high temperature to obtain a metal sulfide semiconductor nanocrystal. The halogen ion in the cationic precursor containing the halogen, and the second oil-soluble organic ligand are bound on the surface of the metal sulfide semiconductor nanocrystal. In addition, excess thiol can also be bound on the surface of the metal sulfide semiconductor nanocrystal as surface ligands. When the amount of thiol added is greater than the amount needed for nucleation of the metal sulfide semiconductor nanocrystal growth, it is indicated that the thiol is excessive.

In some embodiments, the anionic precursor is a sulfur element. After the sulfur element is mixed with the second oil-soluble organic ligand, the formed sulfur ion reacts with a metal ion in the cationic precursor at a high temperature to nucleate to obtain a sulfide semiconductor nanocrystal. The halogen ion in the cationic precursor containing the halogen, and the second oil-soluble organic ligand are bound on the surface of the metal sulfide semiconductor nanocrystal.

In some embodiments, the anionic precursor is a thiol with a carbon number of eight or more and a sulfur element, where after the sulfur element is mixed with the second oil-soluble organic ligand, the formed sulfur ion reacts with a metal ion in the cationic precursor at a high temperature to nucleate to obtain a sulfide semiconductor nanocrystal. The halogen ion in the cationic precursor containing the halogen, and the second oil-soluble organic ligand are bound on the surface of the metal sulfide semiconductor nanocrystal. In addition, excess thiol can also be bound on the surface of the metal sulfide semiconductor nanocrystal as surface ligands. When the amount of thiol added is greater than the amount needed for nucleation of the metal sulfide semiconductor nanocrystal growth, it is indicated that the thiol is excessive.

In some embodiments, the thiol with a carbon number of eight or more includes one or more of an octanethiol, a nonanethiol, a decanethiol, an undecanethiol, a dodecanethiol, a tridecanethiol, a tetradecanethiol, a pentadecylthiol, a hexadecanethiol, a heptadecanethiol and an octadecanethiol.

In some embodiments, the metal halide includes one or more of chloride, bromide, and iodide of zinc element; or one or more of chloride, bromide, and iodide of tin element; or one or more of chloride, bromide, and iodide of germanium element. For example, the metal halide can include one or more of ZnCl₂, ZnBr₂, and ZnI₂; or one or more of SnCl₂, SnBr₂ and SnI₂; or one or more of GeCl₂, GeBr₂, and GeI₂, etc.

Further, in some embodiments, the metal halide includes ZnCl₂, SnCl₂, GeCl₂, etc. Since the atomic radius of chlorine is small compared to bromine and iodine, when it is used as a surface ligand on the surface of the particle, the distance that an electron needs to travel during transport is small, which can improve the electron transportability.

In some embodiments, the second oil-soluble organic ligand includes one or more of a substituted or unsubstituted alkylaminophosphine, a substituted or unsubstituted alkoxyphosphine, a substituted or unsubstituted silylphosphine, and an alkylphosphine having a side chain with a carbon number of four or more.

Further, in some embodiments, the second oil-soluble organic ligand is substituted or unsubstituted alkylaminophosphine that is bonded to cations on the surface of the inorganic semiconductor nanocrystal by a lone electron pair of P and a hydrogen bond in —NH₂ simultaneously. Since an ionic bond of the halogen ligand is strong, the bond between the alkylaminophosphine and the surface of the particle is strong and the oil-soluble organic ligand is not easy to fall off. In addition, when the alkylaminophosphine and the iodine ligand are bonded to the metal sulfide particle, no —OH is bonded to the surface of the metal sulfide particle, which will not cause hydrolysis or oxidation of the metal sulfide particle.

In some embodiments, the first temperature is 110-190° C.

In some embodiments, the second temperature is 110-190° C.

In this embodiment, the prepared inorganic semiconductor nanocrystal is a metal sulfide particle selected from a ZnS particle, a SnS particle, or a GeS particle, but not limited thereto. At a small particle size (2-7 nm), the inorganic semiconductor nanocrystal mainly emits light through defect states. On the other hand, in the method of this embodiment, nucleation occurs at a relatively high temperature (i.e., the third temperature), and by controlling the particle size, the prepared inorganic semiconductor nanocrystal has fewer surface defects and may realize no emission peak in the visible band. The third temperature is 210-350° C. In some embodiments, the third temperature is 230-300° C.

In some embodiments, the first mixture further includes a doped metal salt. The presence of the oil-soluble organic ligand can relatively greatly reduce the electron transport performance. On the other hand, doping with the metal element can reduce the injection barrier of the electron transport layer to the light-emitting layer or form excess free electrons, which can improve the electron transport performance to a certain extent. As such, the electron transport rate and hole transport rate in the device can be further adjusted and the light-emitting efficiency of the light-emitting layer can be further improved.

Further, in some embodiments, the doped metal element accounts for 0.5-10% of the inorganic semiconductor nanocrystal in terms of mass percentage.

Further, in some embodiments, the doped metal element includes one or more of Mg, Mn, Al, Y, V, and Ni.

Further, in some embodiments, the inorganic semiconductor nanocrystal includes a ZnO particle, a ZnS particle, or a SnO particle, and the doped metal element is Al, V, or Y. The HOMO energy levels of these inorganic semiconductor nanocrystals can better match the HOMO energy levels of the quantum dots in the light-emitting layer. Doping ions can reduce the injection barrier of the electron transport layer to the light-emitting layer, thereby ensuring the effectiveness of the electron transport between the materials of the transport layer and the light-emitting layer. Specifically, the doped metal element is Y.

An embodiment of the present disclosure provides a method for preparing a composite material including the following processes.

A cationic precursor and a first oil-soluble organic ligand are dispersed into a solvent and heated at a first temperature to obtain a first mixture, where the cationic precursor is a metal halide.

An anionic precursor and a second oil-soluble organic ligand are dispersed into a solvent and heated at a second temperature to obtain a second mixture, where the anionic precursor is a thiol with a carbon number of eight or more and/or a sulfur element.

The first mixture is heated at a third temperature, and the second mixture is injected during the heating process for a crystal growth of an inorganic semiconductor nanocrystal to obtain a composite material, where the third temperature is higher than the first temperature and the second temperature.

In this embodiment, the cationic precursor containing a halogen reacts with the anionic precursor containing a sulfur at high temperature to obtain a metal sulfide semiconductor nanocrystal. The halogen ion in the cationic precursor containing the halogen, the first oil-soluble organic ligand, and the second oil-soluble organic ligand are bound on the surface of the metal sulfide semiconductor nanocrystal. The composite material obtained by the reaction at high temperature has small and uniform size and fewer surface defects. Further, the composite material has no emission peak in the visible band, and does not interfere with the emission of the light-emitting layer in a device structure. The metal sulfide semiconductor nanocrystal has the following mixed ligands on the surface thereof: the halogen ligand, the first oil-soluble organic ligand and the second oil-soluble organic ligand that make the composite material oil-soluble. In the composite material, the halogen ligand can improve the electron transport performance, and the oil-soluble organic ligand can effectively reduce the electron transport rate, so that the electron transport performance of the material may be adjusted, thereby adjusting the electron transport rate and the hole transport rate in the device, and hence improving the light-emitting efficiency of the light-emitting layer.

In some embodiments, the anionic precursor is a thiol with a carbon number of eight or more. The cationic precursor containing a halogen undergoes an alcoholysis reaction with the thiol at high temperature to obtain a metal sulfide semiconductor nanocrystal. The halogen ion in the cationic precursor containing the halogen, the first oil-soluble organic ligand, and the second oil-soluble organic ligand are bound on the surface of the metal sulfide semiconductor nanocrystal. In addition, excess thiol can also be bound on the surface of the metal sulfide semiconductor nanocrystal as surface ligands. When the amount of thiol added is greater than the amount needed for nucleation of the metal sulfide semiconductor nanocrystal growth, it is indicated that the thiol is excessive.

In some embodiments, the anionic precursor is a sulfur element. After the sulfur element is mixed with the second oil-soluble organic ligand, the formed sulfur ion reacts with a metal ion in the cationic precursor at a high temperature to nucleate to obtain a sulfide semiconductor nanocrystal. The halogen ion in the cationic precursor containing the halogen, the first oil-soluble organic ligand, and the second oil-soluble organic ligand are bound on the surface of the metal sulfide semiconductor nanocrystal.

In some embodiments, the anionic precursor is a thiol with a carbon number of eight or more and a sulfur element, where after the sulfur element is mixed with the second oil-soluble organic ligand, the formed sulfur ion reacts with a metal ion in the cationic precursor at a high temperature to nucleate to obtain a sulfide semiconductor nanocrystal. The halogen ion in the cationic precursor containing the halogen, the first oil-soluble organic ligand, and the second oil-soluble organic ligand are bound on the surface of the metal sulfide semiconductor nanocrystal. In addition, excess thiol can also be bound on the surface of the metal sulfide semiconductor nanocrystal as surface ligands. When the amount of thiol added is greater than the amount needed for nucleation of the metal sulfide semiconductor nanocrystal growth, it is indicated that the thiol is excessive.

In some embodiments, the thiol with a carbon number of eight or more includes one or more of an octanethiol, a nonanethiol, a decanethiol, an undecanethiol, a dodecanethiol, a tridecanethiol, a tetradecanethiol, a pentadecylthiol, a hexadecanethiol, a heptadecanethiol and an octadecanethiol.

In some embodiments, the first oil-soluble organic ligand includes one or more of an organic carboxylic acid with a carbon number of eight or more, an organic phosphoric acid with a carbon number of eight or more, a primary amine with a carbon number of eight or more, and a secondary or tertiary amine having a side chain with a carbon number of four or more; and/or the second oil-soluble organic ligand includes one or more of a substituted or unsubstituted alkylaminophosphine, a substituted or unsubstituted alkoxyphosphine, a substituted or unsubstituted silylphosphine, and an alkylphosphine having a side chain with a carbon number of four or more.

Further, in some embodiments, the first oil-soluble organic ligand is an organic phosphoric acid with a carbon number of eight or more, and the second oil-soluble organic ligand is a substituted or unsubstituted alkylaminophosphine. The organic phosphoric acid is bonded to cations on the surface of the inorganic semiconductor nanocrystal by an ionic bond. The alkylaminophosphine is bonded to cations on the surface of the inorganic semiconductor nanocrystal by a lone electron pair of P and a hydrogen bond in —NH₂ simultaneously. These two bonds are strong and hence the oil-soluble organic ligand is not easy to fall off, thereby ensuring the solubility and transportability of the composite material. Further, these two types of ligands are not bonded to surface ions of the inorganic semiconductor nanocrystal through a —OH, and hence will not undergo hydrolysis.

Further, in some embodiments, the anionic precursor is a thiol with 8 or more carbon atom, or a thiol and a sulfur element, where the amount of thiol added is greater than the amount needed for nucleation of the semiconductor nanocrystal. The first oil-soluble organic ligand is organic phosphoric acid with a carbon number of eight or more, and the second oil-soluble organic ligand is substituted or unsubstituted alkylaminophosphine. When the amount of thiol added is greater than the amount needed for nucleation of the metal sulfide semiconductor nanocrystal growth, it is indicated that the thiol is excessive. The excess thiol can also be bound on the surface of the metal sulfide semiconductor nanocrystal as surface ligands. The organic phosphoric acid is bonded to cations on the surface of the inorganic semiconductor nanocrystal by an ionic bond. The thiol is bonded to cations on the surface of the inorganic semiconductor nanocrystal by a hydrogen bond. The alkylaminophosphine is bonded to cations on the surface of the inorganic semiconductor nanocrystal by a lone electron pair of P and a hydrogen bond in —NH₂ simultaneously. These bonds are strong and hence the oil-soluble organic ligand is not easy to fall off, thereby ensuring the solubility and transportability of the composite material. Further, these two types of ligands are not bonded to surface ions of the inorganic semiconductor nanocrystal through a —OH, and hence will not undergo hydrolysis.

In some embodiments, the first temperature is 110-190° C.

In some embodiments, the second temperature is 110-190° C.

In this embodiment, the prepared inorganic semiconductor nanocrystal is a metal sulfide particle selected from a ZnS particle, a SnS particle, or a GeS particle, but not limited thereto. At a small particle size (2-7 nm), the inorganic semiconductor nanocrystal mainly emits light through defect states. On the other hand, in the method of this embodiment, nucleation occurs at a relatively high temperature (i.e., the third temperature), and by controlling the particle size, the prepared inorganic semiconductor nanocrystal has fewer surface defects and may realize no emission peak in the visible band. The third temperature is 210-350° C. In some embodiments, the third temperature is 230-300° C.

In some embodiments, the first mixture further includes a doped metal salt. The presence of the oil-soluble organic ligand can relatively greatly reduce the electron transport performance. On the other hand, doping with the metal element can reduce the injection barrier of the electron transport layer to the light-emitting layer or form excess free electrons, which can improve the electron transport performance to a certain extent. As such, the electron transport rate and hole transport rate in the device can be further adjusted and the light-emitting efficiency of the light-emitting layer can be further improved.

Further, in some embodiments, the doped metal element accounts for 0.5-10% of the inorganic semiconductor nanocrystal in terms of mass percentage.

Further, in some embodiments, the doped metal element includes one or more of Mg, Mn, Al, Y, V, and Ni.

Further, in some embodiments, the inorganic semiconductor nanocrystal includes a ZnO particle, a ZnS particle, or a SnO particle, and the doped metal element is Al, V, or Y. The HOMO energy levels of these inorganic semiconductor nanocrystals can better match the HOMO energy levels of the quantum dots in the light-emitting layer. Doping ions can reduce the injection barrier of the electron transport layer to the light-emitting layer, thereby ensuring the effectiveness of the electron transport between the materials of the transport layer and the light-emitting layer. Specifically, the doped metal element is Y.

An embodiment of the present disclosure provides a method for preparing a composite material including the following processes.

A cationic precursor is dispersed into a solvent and heated at a first temperature to obtain a first mixture, where the cationic precursor is a metal halide.

An anionic precursor is dispersed into a solvent and heated at a second temperature to obtain a second mixture, where the anionic precursor is a thiol with a carbon number of eight or more and/or a sulfur element.

The first mixture is heated at a third temperature, and the second mixture is injected during the heating process for a crystal growth of an inorganic semiconductor nanocrystal. After the crystal growth is completed, a third oil-soluble organic ligand is added during the cooling process, so that the third oil-soluble organic ligand is bound on the surface of the semiconductor nanocrystal to obtain a composite material. The third oil-soluble organic ligand is a thiol with a carbon number of eight or more. The third temperature is higher than the first temperature and the second temperature.

In this embodiment, the cationic precursor containing a halogen reacts with the anionic precursor containing a sulfur at high temperature to obtain a metal sulfide semiconductor nanocrystal. The halogen ion in the cationic precursor containing the halogen and the third oil-soluble organic ligand are bound on the surface of the metal sulfide semiconductor nanocrystal. The composite material obtained by the reaction at high temperature has small and uniform size and fewer surface defects. Further, the composite material has no emission peak in the visible band, and does not interfere with the emission of the light-emitting layer in a device structure. The metal sulfide semiconductor nanocrystal has the following mixed ligands on the surface thereof: the halogen ligand and the oil-soluble organic ligand that makes the composite material oil-soluble. In the composite material, the halogen ligand can improve the electron transport performance, and the oil-soluble organic ligand can effectively reduce the electron transport rate, so that the electron transport performance of the material may be adjusted, thereby adjusting the electron transport rate and the hole transport rate in the device, and hence improving the light-emitting efficiency of the light-emitting layer.

In some embodiments, the anionic precursor is a thiol with a carbon number of eight or more. The cationic precursor containing a halogen undergoes an alcoholysis reaction with the thiol at high temperature to obtain a metal sulfide semiconductor nanocrystal. The halogen ion in the cationic precursor containing the halogen and the third oil-soluble organic ligand are bound on the surface of the metal sulfide semiconductor nanocrystal. In addition, excess thiol can also be bound on the surface of the metal sulfide semiconductor nanocrystal as surface ligands. When the amount of thiol added is greater than the amount needed for nucleation of the metal sulfide semiconductor nanocrystal growth, it is indicated that the thiol is excessive.

In some embodiments, the anionic precursor is a sulfur element that is added in a form of sulfur-non-coordinating solvent after mixing with a non-coordinating solvent. The sulfur element is dispersed in the non-coordinating solvent to form a uniform liquid, which is convenient for a subsequent injection. The cationic precursor containing a halogen reacts with the sulfur element at high temperature to obtain a metal sulfide semiconductor nanocrystal. The halogen ion in the cationic precursor containing the halogen and the third oil-soluble organic ligand are bound on the surface of the metal sulfide semiconductor nanocrystal. It should be noted that the non-coordinating solvent can be used as a ligand to be bound on the surface of the metal sulfide semiconductor nanocrystal in addition to dispersing the sulfur element.

In some embodiments, the sulfur-non-coordinating solvent includes one or more of a sulfur-dodecene, a sulfur-tetradecene, a sulfur-hexadecene, a sulfur-octadecene, a sulfur-tributylphosphine, a sulfur-triheptylphosphine, a sulfur-trioctylphosphine, a sulfur-tri (dimethylamino) phosphine, a sulfur-tri (diethylamino) phosphine, a sulfur-tri (trimethylsilyl) phosphine, a sulfur-dibenzyldiethylaminophosphine and a sulfur-(diisopropylamino) methoxyphosphine, etc.

In some embodiments, the anionic precursor is a thiol with a carbon number of eight or more and a sulfur element, where the sulfur element is added in a form of sulfur-non-coordinating solvent after mixing with a non-coordinating solvent. The sulfur element is dispersed in the non-coordinating solvent to form a uniform liquid, which is convenient for a subsequent injection. The cationic precursor containing a halogen reacts with the thiol and the sulfur element at high temperature to obtain a metal sulfide semiconductor nanocrystal. The halogen ion in the cationic precursor containing the halogen and the third oil-soluble organic ligand are bound on the surface of the metal sulfide semiconductor nanocrystal. In addition, excess thiol can also be bound on the surface of the metal sulfide semiconductor nanocrystal as surface ligands. When the amount of thiol added is greater than the amount needed for nucleation of the metal sulfide semiconductor nanocrystal growth, it is indicated that the thiol is excessive. It should be noted that the non-coordinating solvent can be used as a ligand to be bound on the surface of the metal sulfide semiconductor nanocrystal in addition to dispersing the sulfur element.

In some embodiments, the sulfur-non-coordinating solvent includes one or more of a sulfur-dodecene, a sulfur-tetradecene, a sulfur-hexadecene, a sulfur-octadecene, a sulfur-tributylphosphine, a sulfur-triheptylphosphine, a sulfur-trioctylphosphine, a sulfur-tri (dimethylamino) phosphine, a sulfur-tri (diethylamino) phosphine, a sulfur-tri (trimethylsilyl) phosphine, a sulfur-dibenzyldiethylaminophosphine and a sulfur-(diisopropylamino) methoxyphosphine, etc.

In some embodiments, the thiol with a carbon number of eight or more includes one or more of an octanethiol, a nonanethiol, a decanethiol, an undecanethiol, a dodecanethiol, a tridecanethiol, a tetradecanethiol, a pentadecylthiol, a hexadecanethiol, a heptadecanethiol and an octadecanethiol.

In some embodiments, the metal halide includes one or more of chloride, bromide, and iodide of zinc element; or one or more of chloride, bromide, and iodide of tin element; or one or more of chloride, bromide, and iodide of germanium element. For example, the metal halide can include one or more of ZnCl₂, ZnBr₂, and ZnI₂; or one or more of SnCl₂, SnBr₂ and SnI₂; or one or more of GeCl₂, GeBr₂, and GeI₂, etc.

Further, in some embodiments, the metal halide includes ZnCl₂, SnCl₂, GeCl₂, etc. Since the atomic radius of chlorine is small compared to bromine and iodine, when it is used as a surface ligand on the surface of the particle, the distance that an electron needs to travel during transport is small, which can improve the electron transportability.

In some embodiments, the first temperature is 110-190° C.

In some embodiments, the second temperature is 110-190° C.

In this embodiment, the prepared inorganic semiconductor nanocrystal is a metal sulfide particle selected from a ZnS particle, a SnS particle, or a GeS particle, but not limited thereto. At a small particle size (2-7 nm), the inorganic semiconductor nanocrystal mainly emits light through defect states. On the other hand, in the method of this embodiment, nucleation occurs at a relatively high temperature (i.e., the third temperature), and by controlling the particle size, the prepared inorganic semiconductor nanocrystal has fewer surface defects and may realize no emission peak in the visible band. The third temperature is 210-350° C. In some embodiments, the third temperature is 230-300° C.

In some embodiments, the first mixture further includes a doped metal salt. The presence of the oil-soluble organic ligand can relatively greatly reduce the electron transport performance. On the other hand, doping with the metal element can reduce the injection barrier of the electron transport layer to the light-emitting layer or form excess free electrons, which can improve the electron transport performance to a certain extent. As such, the electron transport rate and hole transport rate in the device can be further adjusted and the light-emitting efficiency of the light-emitting layer can be further improved.

Further, in some embodiments, the doped metal element accounts for 0.5-10% of the inorganic semiconductor nanocrystal in terms of mass percentage.

Further, in some embodiments, the doped metal element includes one or more of Mg, Mn, Al, Y, V, and Ni.

Further, in some embodiments, the inorganic semiconductor nanocrystal includes a ZnO particle, a ZnS particle, or a SnO particle, and the doped metal element is Al, V, or Y. The HOMO energy levels of these inorganic semiconductor nanocrystals can better match the HOMO energy levels of the quantum dots in the light-emitting layer. Doping ions can reduce the injection barrier of the electron transport layer to the light-emitting layer, thereby ensuring the effectiveness of the electron transport between the materials of the transport layer and the light-emitting layer. Specifically, the doped metal element is Y.

An embodiment of the present disclosure provides a quantum dot light-emitting diode including an anode, a cathode, and a laminate disposed between the anode and the cathode. The laminate includes a quantum dot light-emitting layer disposed near the anode side and an electron transport layer disposed near the cathode side. The electron transport layer includes at least one first electron transport layer with a material including a particle that is an inorganic semiconductor nanocrystal, a halogen ligand and oil-soluble organic ligand which are bound on the surface of the particle.

In the material of the first electron transport layer provided by the present disclosure, the particle has the following mixed ligands on the surface thereof: the halogen ligand and the oil-soluble organic ligand that makes the material of the first electron transport layer oil-soluble. In the oil-soluble material of the first electron transport layer of the present disclosure, the halogen ligand may improve the electron transport performance, and the oil-soluble organic ligand may effectively reduce the electron transport rate, so that the electron transport performance of the material may be adjusted, thereby adjusting the electron transport rate and the hole transport rate in a device, and further improving the light-emitting efficiency of a light-emitting layer. It should be noted that the material of the first electron transport layer described in the embodiments of the present disclosure is the composite material in this specification with details described above, and will not be repeated here.

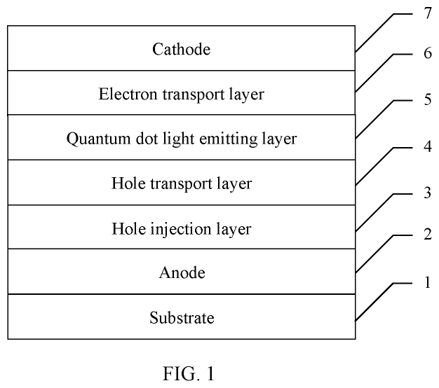

Consistent with embodiments of the disclosure, the quantum dot light-emitting diode can be in many forms, and can have a normal structure or a reversed structure. FIG. 1 schematically shows a quantum dot light-emitting diode having a normal structure. Specifically, as shown in FIG. 1, the quantum dot light-emitting diode includes a substrate 1, an anode 2, a hole injection layer 3, a hole transport layer 4, a quantum dot light-emitting layer 5, an electron transport layer 6, and a cathode 7 layered from bottom to top. The electron transport layer 6 includes at least one first electron transport layer. The material of the first electron transport layer includes a particle that is an inorganic semiconductor nanocrystal, a halogen ligand and oil-soluble organic ligand which are bound on the surface of the particle. The structure of the electron transport layer 6 is described in detail below.

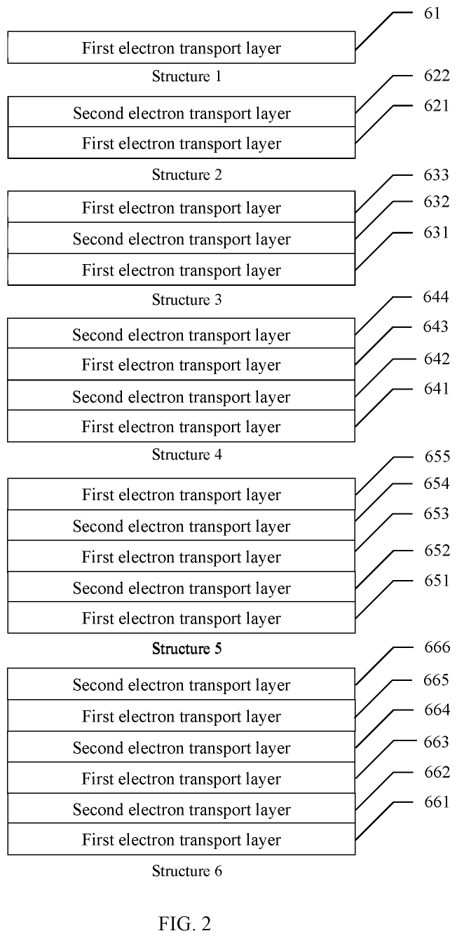

In some embodiments, the material of the quantum dot light-emitting layer is a water-soluble quantum dot, and the electron transport layer 6 is a first electron transport layer 61, as in structure 1 shown in FIG. 2. In the material of the first electron transport layer, the particle has the following mixed ligands on the surface thereof: the halogen ligand and the oil-soluble organic ligand that makes the composite material oil-soluble. In the oil-soluble material of the first electron transport layer, the halogen ligand may improve the electron transport performance, and the oil-soluble organic ligand may effectively reduce the electron transport rate, so that the electron transport performance of the material may be adjusted, thereby adjusting the electron transport rate and the hole transport rate in the device, and further improving the light-emitting efficiency of the light-emitting layer.

In some embodiments, the material of the quantum dot light-emitting layer is a water-soluble quantum dot, and the electron transport layer further includes at least one second electron transport layer that includes a water-soluble electron transport material. The first layer of first electron transport layer is stacked on the quantum dot light-emitting layer, and the first layer of second electron transport layer is stacked on the first layer of first electron transport layer. Each subsequent electron transport layer is stacked on each preceding different type of electron transport layer. In order to maintain a proper electron transport distance and keep the device not too thick, the total number of layers of the first electron transport layer and the second electron transport layer is 3-6. In a device, water-soluble and oil-soluble functional layers need to be arranged alternately, i.e., neighboring functional layers cannot be both water-soluble or both oil-soluble. In addition, since the water-soluble electron transport material does not have an organic ligand on the surface, alternately stacking the water-soluble layer and the oil-soluble layer being in a same functional layer can further reduce the electron transport distance and improve the efficiency of the electron transport. The cases where the total number of the first electron transport layer and the second electron transport layer is 2-6 will be described one by one with reference to FIG. 2. It should be noted that the total number of layers of the first electron transport layer and the total number of layers of the second electron transport layer may be same or different.

In some embodiments, as shown in structure 2 in FIG. 2, the electron transport layer 6 includes a first electron transport layer 621 and a second electron transport layer 622 one stacked on another, where the first electron transport layer 621 is close to a quantum dot light-emitting layer and the material of the quantum dot light-emitting layer includes a water-soluble quantum dot.

In some embodiments, as shown in structure 3 in FIG. 2, the electron transport layer 6 includes a first electron transport layer 631, a second electron transport layer 632, and a first electron transport layer 633 stacked sequentially, where the first electron transport layer 631 abuts a quantum dot light-emitting layer and the material of the quantum dot light-emitting layer includes a water-soluble quantum dot.

In some embodiments, as shown in structure 4 in FIG. 2, the electron transport layer 6 includes a first electron transport layer 641, a second electron transport layer 642, a first electron transport layer 643, and a second electron transport layer 644 stacked sequentially, where the first electron transport layer 641 abuts a quantum dot light-emitting layer and the material of the quantum dot light-emitting layer includes a water-soluble quantum dot.

In some embodiments, as shown in structure 5 in FIG. 2, the electron transport layer 6 includes a first electron transport layer 651, a second electron transport layer 652, a first electron transport layer 653, a second electron transport layer 654, and a first electron transport layer 655 stacked sequentially, where the first electron transport layer 651 abuts a quantum dot light-emitting layer and the material of the quantum dot light-emitting layer includes a water-soluble quantum dot.

In some embodiments, as shown in structure 6 in FIG. 2, the electron transport layer 6 includes a first electron transport layer 661, a second electron transport layer 662, a first electron transport layer 663, a second electron transport layer 664, a first electron transport layer 665, and a second electron transport layer 666 stacked sequentially, where the first electron transport layer 661 abuts a quantum dot light-emitting layer and the material of the quantum dot light-emitting layer includes a water-soluble quantum dot.

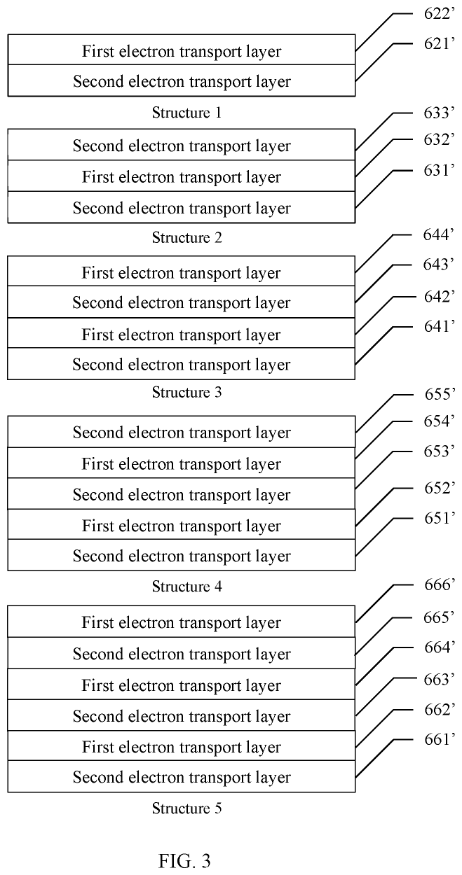

In some embodiments, the material of the quantum dot light-emitting layer is an oil-soluble quantum dot, and the electron transport layer further includes at least one second electron transport layer that is a water-soluble electron transport material. The first layer of second electron transport layer is stacked on the quantum dot light-emitting layer, and the first layer of first electron transport layer is stacked on the first layer of second electron transport layer. Each subsequent electron transport layer is stacked on each preceding different type of electron transport layer. In order to maintain a proper electron transport distance and keep the device not too thick, the total number of layers of the first electron transport layer and the second electron transport layer is 3-6. In a device, water-soluble and oil-soluble functional layers need to be arranged alternately, i.e., neighboring functional layers cannot be both water-soluble or both oil-soluble. In addition, since the water-soluble electron transport material does not have an organic ligand on the surface, alternately stacking the water-soluble layer and the oil-soluble layer being in a same functional layer can further reduce the electron transport distance and improve the efficiency of the electron transport. The cases where the total number of the first electron transport layer and the second electron transport layer is 2-6 will be described one by one with reference to FIG. 3. It should be noted that the total number of layers of the first electron transport layer and the total number of layers of the second electron transport layer may be same or different.

In some embodiments, as shown in structure 1 in FIG. 3, the electron transport layer 6 includes a second electron transport layer 621′ and a first electron transport layer 622′ one stacked on another, where the second electron transport layer 621′ is close to a quantum dot light-emitting layer and the material of the quantum dot light-emitting layer includes an oil-soluble quantum dot.

In some embodiments, as shown in structure 2 in FIG. 3, the electron transport layer 6 includes a second electron transport layer 631′, a first electron transport layer 632′, and a second electron transport layer 633′ stacked sequentially, where the second electron transport layer 631′ abuts a quantum dot light-emitting layer and the material of the quantum dot light-emitting layer includes an oil-soluble quantum dot.

In some embodiments, as shown in structure 3 in FIG. 3, the electron transport layer 6 includes a second electron transport layer 641′, a first electron transport layer 642′, a second electron transport layer 643′, and a first electron transport layer 644′ stacked sequentially, where the second electron transport layer 641′ abuts a quantum dot light-emitting layer and the material of the quantum dot light-emitting layer includes an oil-soluble quantum dot.

In some embodiments, as shown in structure 4 in FIG. 3, the electron transport layer 6 includes a second electron transport layer 651′, a first electron transport layer 652′, a second electron transport layer 653′, a first electron transport layer 654′, and a second electron transport layer 655′ stacked sequentially, where the second electron transport layer 651′ abuts a quantum dot light-emitting layer and the material of the quantum dot light-emitting layer includes an oil-soluble quantum dot.

In some embodiments, as shown in structure 5 in FIG. 3, the electron transport layer 6 includes a second electron transport layer 661′, a first electron transport layer 662′, a second electron transport layer 663′, a first electron transport layer 664′, a second electron transport layer 665′, and a first electron transport layer 666′ stacked sequentially, where the second electron transport layer 661′ abuts a quantum dot light-emitting layer and the material of the quantum dot light-emitting layer includes a water-soluble quantum dot.

Further, in some embodiments, the material of the second electron transport layer may include materials with good electron transport properties, e.g., including one or more of an n-type ZnO particle, a TiO₂ particle, a Ca particle, a Ba particle, a ZrO₂ particle, a CsF particle, a LiF particle, a CsCO₃ particle, and an Alq3 particle, etc. These water-soluble electron transport materials can be dispersed in water, methanol, ethanol, propanol, acetone, or another solution in the form of ions. The nanoparticle is 5-15 nm in size and has no surface ligand.

Further, in some embodiments, the water-soluble quantum dot is a quantum dot with a water-soluble ligand bound on the surface.

Further, in some embodiments, the water-soluble ligand includes one or more of a halogen ion ligand, a mercapto alcohol with a carbon number less than eight, a mercaptoamine with a carbon number less than eight, and a mercapto acid with a carbon number less than eight. As an example, the halogen ion ligand includes one or more of a chloride ion, a bromide ion, and an iodide ion. As an example, the mercapto alcohol with a carbon number less than eight includes one or more of 2-mercaptoethanol, 3-mercapto-1-propanol, 4-mercapto-1-butanol, 5-mercapto-1-pentanol, and 6-mercapto-1-hexanol, etc. As an example, the mercaptoamine with a carbon number less than eight includes one or more of 2-mercaptoethylamine, 3-mercaptopropylamine, 4-mercaptobutylamine, 5-mercaptopentamine, 6-mercaptohexylamine, and 2-amino-3-mercaptopropionic acid, etc. As an example, the mercapto acid with a carbon number less than eight includes one or more of 2-mercaptoacetic acid, 3-mercaptopropionic acid, 4-mercaptobutanoic acid, mercaptosuccinic acid, 6-mercaptohexanoic acid, 4-mercaptobenzoic acid and semicystine, etc.

Further, in some embodiments, the quantum dot includes one or more of Au, Ag, Cu, Pt, C, CdSe, CdS, CdTe, CdS, CdZnSe, CdSeS, PbSeS, ZnCdTe, CdS/ZnS, CdZnS/ZnS, CdZnSe/ZnSe, CdSeS/CdSeS/CdS, CdSe/CdZnSe/CdZnSe/ZnSe, CdZnSe/CdZnSe/ZnSe, CdS/CdZnS/CdZnS/ZnS, NaYF₄, NaCdF₄, CdZnSeS, CdSe/ZnS, CdZnSe/ZnS, CdSe/CdS/ZnS, CdSe/ZnSe/ZnS, CdZnSe/CdZnS/ZnS and InP/ZnS, etc.

Further, in some embodiments, the oil-soluble quantum dot is a quantum dot with an oil-soluble organic ligand bound on the surface. Types of the quantum dot are described above and will not be repeated here.

Further, in some embodiments, the oil-soluble organic ligand includes one or more of a linear organic ligands with a carbon number of eight or more, a secondary or tertiary amines having a side chain with a carbon number of four or more, a substituted or unsubstituted alkylaminophosphines, a substituted or unsubstituted alkoxyphosphines, a substituted or unsubstituted silylphosphines, and an alkylphosphines having a side chain with a carbon number of four or more. Specific types of the above described oil-soluble organic ligands are described below, and will not be repeated here.

In some embodiments, the thickness of the electron transport layer is 20-60 nm.

In some embodiments, the substrate may be a substrate of rigid material, e.g., glass, etc., or a substrate of flexible material, e.g., one of PET or PI, etc.

In some embodiments, the anode may include one or more of indium-doped tin oxide (ITO), fluorine-doped tin oxide (FTO), antimony-doped tin oxide (ATO), and aluminum-doped zinc oxide (AZO), etc.

In some embodiments, the material of the hole transport layer may include one or more of NiO, CuO, CuS, TFB, PVK, Poly-TPD, TCTA, and CBP, etc. Furthermore, the thickness of the hole transport layer is 20-40 nm.

In some embodiments, the thickness of the quantum dot light-emitting layer is 20-60 nm.

In some embodiments, the cathode may include aluminum (Al) electrode, silver (Ag) electrode, and gold (Au) electrode, etc. Furthermore, the thickness of the cathode is 60-100 nm.

It should be noted that the quantum dot light-emitting diode of the present disclosure may further include one or more layers of the following functional layers: an electron blocking layer disposed between the quantum dot light-emitting layer and the electron transport layer, and an electron injection layer disposed between the electron transport layer and the cathode.

An embodiment of the present disclosure also provides a method for preparing a quantum dot light-emitting diode with a normal structure as shown in FIG. 1, including, providing a substrate, forming an anode over the substrate, forming a hole transport layer over the anode, forming a quantum dot light-emitting layer over the hole transport layer, forming an electron transport layer over the quantum dot light-emitting layer, and forming a cathode over the electron transport layer, to obtain the quantum dot light-emitting diode.

The electron transport layer includes at least one first electron transport layer with a material including a particle that is an inorganic semiconductor nanocrystal, a halogen ligand and oil-soluble organic ligand which are bound on the surface of the particle.

In the present disclosure, a method for preparing each layer may be a chemical method or a physical method. The chemical method includes but is not limited to one or more of a chemical vapor deposition method, a continuous ion layer adsorption and reaction method, an anodizing method, an electrolytic deposition method, and a co-precipitation. The physical method includes but is not limited to one or more of a solution method (e.g., spin coating, printing, blade coating, dip-pulling, dipping, spraying, roll coating, casting, slot coating, or strip coating, etc.), an evaporation method (e.g., thermal evaporation, electron beam evaporation, magnetron sputtering, or multi-arc ion coating, etc.), and a deposition method (e.g., physical vapor deposition, atomic layer deposition, or pulse laser deposition, etc.).

It should be noted that the material of the first electron transport layer described in the embodiments of the present disclosure is the composite material in this specification, so the method for preparing the material of the first electron transport layer is also the method for preparing the composite material, which is described above, and will not be repeated here. The disclosure will be described in detail below with reference to some specific embodiments.

In one embodiment, the preparation process of a composite material (ZnO particles with surface ligands of octadecenoic acid (OA) and Cl⁻) is as follows.

4 mmol ZnCl₂ is mixed with 4 mL OA and 10 mL octadecene (ODE), and heated to 150° C. and maintained for 60 minutes under an Ar atmosphere, to obtain a cationic precursor solution.

4 mmol dodecanol is mixed with 10 mL ODE, and heated to 180° C. and maintained for 60 minutes under an Ar atmosphere, to obtain an anionic precursor solution.

The cationic precursor solution is heated to 230° C., the anionic precursor solution is injected, and then the temperature is maintained for 60 minutes, to obtain ZnO particles with surface ligands of OA and Cl⁻, that is, the composite material of this embodiment.

In another embodiment, the preparation process of a composite material (SnO particles with surface ligands of OA and Cl⁻) is as follows.

4 mmol SnCl₂ is mixed with 10 mmol stearic acid and 10 mL ODE, and heated to 150° C. and maintained for 60 minutes under an Ar atmosphere, to obtain a cationic precursor solution.

4 mmol stearyl alcohol is mixed with 10 mL ODE, and heated to 180° C. and maintained for 60 minutes under an Ar atmosphere, to obtain an anionic precursor solution.

The cationic precursor solution is heated to 250° C., the anionic precursor solution is injected, and then the temperature is maintained for 40 minutes, to obtain SnO particles with surface ligands of stearic acid and that is, the composite material of this embodiment.

In another embodiment, the preparation process of a composite material (ZnS particles with surface ligands of octadecyl phosphoric acid, octyl mercaptan, and Br) is as follows.

4 mmol ZnBr₂ is mixed with 4 mL octadecyl phosphoric acid and 10 mL ODE, and heated to 150° C. and maintained for 60 minutes under an Ar atmosphere, to obtain a cationic precursor solution.

4 mmol dodecanethiol is mixed with 10 mL ODE, and heated to 180° C. and maintained for 60 minutes under an Ar atmosphere, to obtain an anionic precursor solution.

The cationic precursor solution is heated to 270° C., the anionic precursor solution is injected, the temperature is maintained at 270° C. for 20 minutes and then cooled to 100° C., and then 0.5 mL octanethiol is added to the reaction solution followed by stirring for 30 mins, to obtain ZnS particles with surface ligands of octadecyl phosphoric acid, octyl mercaptan, and Br, that is, the composite material of this embodiment.

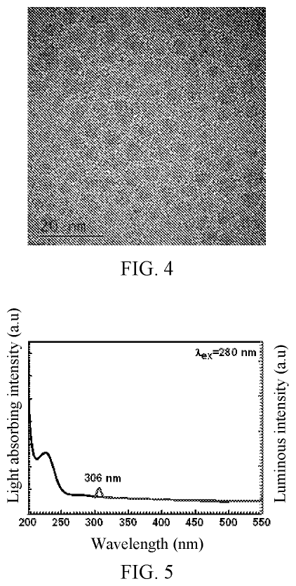

FIG. 4 is a TEM image of the composite material. As shown in FIG. 4, the particle size is 4.7 nm, and the particles are small and uniform. FIG. 5 is an absorption and emission spectra of the composite material, showing that the composite material of this embodiment has no emission peak in the visible band, indicating that the surface of the particle has fewer defects.

In another embodiment, the preparation process of a composite material (SnS particles with surface ligands of octadecyl phosphoric acid, trioctylphosphine, octadecylmercaptan, and I⁻) is as follows.

4 mmol SnI₂ is mixed with 4 mL octadecyl phosphoric acid and 10 mL ODE, and heated to 150° C. and maintained for 60 minutes under an Ar atmosphere, to obtain a cationic precursor solution.

4 mmol sulfur is mixed with 4 mL trioctylphosphine and 10 mL ODE, and heated to 180° C. and maintained for 60 minutes under an Ar atmosphere, to obtain an anionic precursor solution.

The cationic precursor solution is heated to 300° C., the anionic precursor solution is injected, the temperature is maintained at 300° C. for 20 minutes and then cooled to 100° C., and then 1 mL octadecylmercaptan is added to the reaction solution followed by stirring for 30 mins, to obtain SnS particles with surface ligands of octadecyl phosphoric acid, trioctylphosphine, octadecylmercaptan, and I⁻, that is, the composite material of this embodiment.

In another embodiment, the preparation process of a ZnO material with mixed ligands is as follows.

4 mmol ZnCl₂ is mixed with 4 mL OA and 10 mL ODE, and heated to 150° C. and maintained for 60 minutes under an Ar atmosphere, to obtain a cationic precursor solution.

4.8 mmol stearyl alcohol is mixed with 10 mL ODE, and heated to 180° C. and maintained for 60 minutes under an Ar atmosphere, to obtain an anionic precursor solution.

The cationic precursor solution is heated to 280° C., the anionic precursor solution is injected, the temperature is maintained at 280° C. for 10 minutes and then cooled to 150° C., and then 1 mL dodecanethiol is added to the reaction solution followed by stirring for 30 mins, to obtain a ZnO precipitate with surface ligands of OA, dodecanethio, and Cr. The precipitate is dried, and then prepared as a 20 mg/ml heptane solution of ZnO with mixed ligands.

A device is prepared as follows. The device structure includes a glass substrate, an ITO anode, a hole injection layer, a 35 nm hole transport layer, a 20 nm quantum dot light-emitting layer, a 40 nm electron transport layer, and a 100 nm cathode layered from bottom to top. The electron transport layer includes a sequentially stacked laminate of a 20 nm polar ZnO layer and a 20 nm ZnO layer with surface ligands of OA, dodecanethio, and Cl⁻.

The preparation method of a QLED device is as follows.

A hole injection layer and a 35 nm hole transport layer are sequentially coated over an ITO bottom electrode.

A 20 mg/ml light-emitting quantum dot heptane solution is spin coated with a rotation speed of 2000 rpm over the hole transport layer to form a 20 nm quantum dot light-emitting layer.

A methoanol solution of ZnO and a heptane solution of ZnO with mixed ligands of OA, dodecanethio, and Cl⁻ are sequentially coated over the quantum dot light-emitting layer, where the thickness of each layer is 20 nm.

A 100 nm Ag electrode is formed over the electron transport layer using a vapor deposition method.

The manufactured QLED device is encapsulated with ultraviolet curing adhesive to obtain a quantum dot device.

In another embodiment, the preparation process of Y-doped ZnO with mixed ligands is as follows.

0.4 mmol Y(CH₃COO)₂ and 4 mmol ZnCl₂ are mixed with 10 mmol OA and 10 ml ODE, and heated to 150° C. and maintained for 60 minutes under an Ar atmosphere, to obtain a cationic precursor solution.

4.8 mmol stearyl alcohol is mixed with 10 mL ODE, and heated to 180° C. and maintained for 60 minutes under an Ar atmosphere, to obtain an anionic precursor solution.

The cationic precursor solution is heated to 280° C., the anionic precursor solution is injected, the temperature is maintained at 280° C. for 10 minutes and then cooled to 150° C., and then 1 mL dodecanethiol is added to the reaction solution followed by stirring for 30 mins, to obtain a ZnO:Y precipitate with surface ligands of OA, dodecanethio, and Cl⁻. The precipitate is dried, and then prepared as a 20 mg/ml heptane solution of ZnO:Y with mixed ligands.

A device is prepared as follows. The device structure includes a glass substrate, an ITO anode, a hole injection layer, a 35 nm hole transport layer, a 20 nm quantum dot light-emitting layer, a 40 nm electron transport layer, and a 100 nm cathode layered from bottom to top. The electron transport layer includes a sequentially stacked laminate of a 20 nm polar ZnO layer and a 20 nm ZnO:Y layer with surface ligands of OA, dodecanethio, and Cl⁻.

The preparation method of a QLED device is as follows.

A hole injection layer and a 35 nm hole transport layer are sequentially coated over an ITO bottom electrode.

A 20 mg/ml heptane solution of light-emitting quantum dot is spin coated with a rotation speed of 2000 rpm over the hole transport layer to form a 20 nm quantum dot light-emitting layer.

A methoanol solution of ZnO and a heptane solution of ZnO:Y with mixed ligands of OA, dodecanethio, and Cl⁻ are sequentially coated over the quantum dot light-emitting layer, where the thickness of each layer is 20 nm.

A 100 nm Ag electrode is formed over the electron transport layer using a vapor deposition method.

The manufactured QLED device is encapsulated with ultraviolet curing adhesive to obtain a quantum dot device.

In the two embodiments described above, all the structures of the devices are the same, except the difference whether the ZnO is Y-doped in the material of the electron transport layer. The quantum efficiency of the quantum dot device with undoped ZnO as the electron transport layer is 12.5%, and the quantum efficiency of the quantum dot device with ZnO:Y as the electron transport layer is 14.3%, indicating that Y-doped ZnO is beneficial to improve the light-emitting efficiency of the quantum dot device.

In another embodiment, the device structure includes a glass substrate, an ITO anode, a hole injection layer, a 35 nm hole transport layer, a 20 nm quantum dot light-emitting layer, a 40 nm electron transport layer, and a 100 nm cathode layered from bottom to top. The electron transport layer includes a sequentially stacked laminate of a 20 nm polar ZnO layer and a 20 nm ZnO quantum dot layer with surface ligands of OA and Cr.

The preparation method of a QLED device is as follows.

A hole injection layer and a 35 nm hole transport layer are sequentially coated over an ITO bottom electrode.

A 20 mg/ml heptane solution of light-emitting quantum dot is spin coated with a rotation speed of 2000 rpm over the hole transport layer to form a 20 nm quantum dot light-emitting layer.

A methoanol solution of ZnO and a heptane solution of ZnO with mixed ligands of OA and Cl⁻ are sequentially coated over the quantum dot light-emitting layer, where the thickness of each layer is 20 nm.

A 100 nm Ag electrode is formed over the electron transport layer using a vapor deposition method.

The manufactured QLED device is encapsulated with ultraviolet curing adhesive to obtain a quantum dot device.

In another embodiment, the device structure includes a glass substrate, an ITO anode, a hole injection layer, a 35 nm hole transport layer, a 20 nm quantum dot light-emitting layer, a 50 nm electron transport layer, and a 100 nm cathode layered from bottom to top. The electron transport layer includes a sequentially stacked laminate of a 10 nm polar ZnO layer, a 10 nm ZnO quantum dot layer with surface ligands of an octadecyl phosphate and a 10 nm polar ZnO layer, a 10 nm ZnO quantum dot layer with surface ligands of octadecyl phosphate and Cl⁻, and 10 nm polar ZnO layer.

The preparation method of a QLED device is as follows.

A hole injection layer and a 35 nm hole transport layer are sequentially coated over an ITO bottom electrode.

A 20 mg/ml heptane solution of light-emitting quantum dot is spin coated with a rotation speed of 2000 rpm over the hole transport layer to form a 20 nm quantum dot light-emitting layer.

A methoanol solution of ZnO, a heptane solution of ZnO with mixed ligands of octadecyl phosphate and Cl⁻, a methoanol solution of ZnO, a heptane solution of ZnO with mixed ligands of octadecyl phosphate and a methoanol solution of ZnO are sequentially coated over the quantum dot light-emitting layer, where the thickness of each layer is 10 nm.

A 100 nm Ag electrode is formed over the electron transport layer using a vapor deposition method.

The manufactured QLED device is encapsulated with ultraviolet curing adhesive to obtain a quantum dot device.

In another embodiment, the device structure includes a glass substrate, an ITO anode, a hole injection layer, a 20 nm hole transport layer, a 40 nm quantum dot light-emitting layer, a 60 nm electron transport layer, and a 80 nm cathode layered from bottom to top. The electron transport layer includes a sequentially stacked laminate of a 10 nm polar ZnO layer, a 10 nm ZnS:Y quantum dot layer with surface ligands of octanethiol and Br⁻, a 10 nm polar ZnO layer, a 10 nm ZnS:Y quantum dot layer with surface ligands of octanethiol and Br⁻, a 10 nm polar ZnO layer, and a 10 nm ZnS:Y quantum dot layer with surface ligands of octanethiol and Br⁻.

The preparation method of a QLED device is as follows.

A hole injection layer and a 20 nm hole transport layer are sequentially coated over an ITO bottom electrode.

A 20 mg/ml heptane solution of light-emitting quantum dot is spin coated with a rotation speed of 2000 rpm over the hole transport layer to form a 40 nm quantum dot light-emitting layer.

A methoanol solution of ZnO, a heptane solution of ZnS:Y with mixed ligands of octanethiol and Br⁻, a methoanol solution of ZnO, a heptane solution of ZnS:Y with mixed ligands of octanethiol and Br⁻, a methoanol solution of ZnO, and a heptane solution of ZnS:Y with mixed ligands of octanethiol and Br are sequentially coated over the quantum dot light-emitting layer, where the thickness of each layer is 10 nm.

A 80 nm Al electrode is formed over the electron transport layer using a vapor deposition method.

The manufactured QLED device is encapsulated with ultraviolet curing adhesive to obtain a quantum dot device.

In another embodiment, the device structure includes a glass substrate, an ITO anode, a hole injection layer, a 30 nm hole transport layer, a 50 nm quantum dot light-emitting layer, a 60 nm electron transport layer, and a 60 nm cathode layered from bottom to top. The electron transport layer includes a sequentially stacked laminate of a 20 nm polar ZnO layer, a 20 nm ZnO:Mg quantum dot layer with surface ligands of octadecyl acid and Cr.

The preparation method of a QLED device is as follows.

A hole injection layer and a 30 nm hole transport layer are sequentially coated over an ITO bottom electrode.

A 20 mg/ml ethanol solution of light-emitting quantum dot is spin coated with a rotation speed of 2000 rpm over the hole transport layer to form a 50 nm quantum dot light-emitting layer.

A solution of ZnO:Mg is coated over the quantum dot light-emitting layer with a thickness of 60 nm.

A 60 nm Cu electrode is formed over the electron transport layer using a vapor deposition method.

The manufactured QLED device is encapsulated with ultraviolet curing adhesive to obtain a quantum dot device.

In another embodiment, the device structure includes a glass substrate, an ITO anode, a hole injection layer, a 40 nm hole transport layer, a 60 nm quantum dot light-emitting layer, a 50 nm electron transport layer, and a 70 nm cathode layered from bottom to top. The electron transport layer includes a sequentially stacked laminate of a 10 nm ZnS:Mn quantum dot layer with surface ligands of octyl mercaptan and mercapto 3-ylpropionic acid, a 10 nm polar ZnO layer, a 10 nm ZnS:Mn quantum dot layer with surface ligands of octyl mercaptan and mercapto 3-ylpropionic acid, a 10 nm polar ZnO layer, and a 10 nm ZnS:Mn quantum dot layer with surface ligands of octyl mercaptan and mercapto 3-ylpropionic acid.

The preparation method of a QLED device is as follows.

A hole injection layer and a 40 nm hole transport layer are sequentially coated over an ITO bottom electrode.

A 20 mg/ml ethanol solution of light-emitting quantum dot is spin coated with a rotation speed of 2000 rpm over the hole transport layer to form a 60 nm quantum dot light-emitting layer.

A heptane solution of ZnS:Mn with mixed ligands of octyl mercaptan and mercapto 3-ylpropionic acid, a polar ZnO solution, a heptane solution of ZnS:Mn with mixed ligands of octyl mercaptan and mercapto 3-ylpropionic acid, a polar ZnO solution, and a heptane solution of ZnS:Mn with mixed ligands of octyl mercaptan and mercapto 3-ylpropionic acid are sequentially coated on the quantum dot light-emitting layer, where the thickness of each layer is 10 nm.

A 70 nm Al electrode is formed over the electron transport layer using a vapor deposition method.

The manufactured QLED device is encapsulated with ultraviolet curing adhesive to obtain a quantum dot device.

In the composite material provided by the present disclosure, the particle has the following mixed ligands on the surface thereof: the halogen ligand and the oil-soluble organic ligand that makes the composite material oil-soluble. In the composite material of the present disclosure, the halogen ligand may improve the electron transport performance, and the oil-soluble organic ligand may effectively reduce the electron transport rate, so that the electron transport performance of the material may be adjusted, thereby adjusting the electron transport rate and the hole transport rate in a device, and further improving the light-emitting efficiency of a light-emitting layer.

The present disclosure has been described with the above embodiments, but the technical scope of the present disclosure is not limited to the scope described in the above embodiments. Other embodiments of the disclosure will be apparent to those skilled in the art from consideration of the specification and practice of the embodiments disclosed herein. It is intended that the embodiments be considered as example only and not to limit the scope of the disclosure, with a true scope and spirit of the invention being indicated by the claims.

What is claimed is:

1. A composite material comprising:
a particle including an inorganic semiconductor nanocrystal; and
a halogen ligand and an oil-soluble organic ligand bound on a surface of the particle.

2. The composite material of claim 1, wherein the composite material has no emission in a visible band.

3. The composite material of claim 1, wherein a size of the inorganic semiconductor nanocrystal is 2-7 nm.

4. The composite material of claim 1, wherein the inorganic semiconductor nanocrystal includes at least one of:
a metal oxide particle selected from a ZnO particle, a CdO particle, a SnO particle, and a GeO particle; or
a metal sulfide particle selected from a ZnS particle, a SnS particle, and a GeS particle.

5. The composite material of claim 1, wherein the halogen ligand includes one or more of a chloride ion, a bromide ion, and an iodide ion.

6. The composite material of claim 1, wherein the oil-soluble organic ligand includes one or more of a linear organic ligand with a carbon number of eight or more, a secondary or tertiary amine having a side chain with a carbon number of four or more, a substituted or unsubstituted alkylaminophosphine, a substituted or unsubstituted alkoxyphosphine, a substituted or unsubstituted silylphosphine, and an alkylphosphine having a side chain with a carbon number of four or more.

7. The composite material of claim 6, wherein:
the linear organic ligand with a carbon number of eight or more includes one or more of an organic carboxylic acid with a carbon number of eight or more, a thiol with a carbon number of eight or more, an organic phosphoric acid with a carbon number of eight or more, and a primary amine with a carbon number of eight or more;
the substituted or unsubstituted alkylaminophosphine includes one or more of a tri (dimethylamino) phosphine, a tri (diethylamino) phosphine, a tri (dipropylamino) phosphine, a tri (dibutylamino) phosphine, a tri (dipentylamino) phosphine, a tri (dihexylamino) phosphine, a tri (diheptylamino) phosphine, a tri (dioctylamino) phosphine, and a dibenzyldiethylaminophosphine;
the substituted or unsubstituted alkoxyphosphine includes one or more of a tributylphosphine oxide, a tripentylphosphine oxide, a trihexylphosphine oxide, a triheptylphosphine oxide, a trioctylphosphine oxide, a trinonylphosphine oxide, a tridecylphosphine oxide, a diphenylmethoxyphosphine, a diphenylethoxyphosphine, a diphenylpropoxyphosphine, a diphenylbutoxyphosphine, a dimethylphenylphosphine oxide, a diethylphenyloxyphosphine oxide, a dipropylphenylphosphine oxide, a dibutylphenylphosphine oxide, a methyldiphenylphosphine oxide, a ethyldiphenylphosphine oxide, a propyldiphenylphosphine oxide, a butyldiphenylphosphine oxide, and a chloro (diisopropylamino) methoxyphosphorus;
the substituted or unsubstituted silylphosphine includes one or more of a tris (trisilyl) phosphine, a tri (triethylsilyl) phosphine, a tri (tripropylsilyl) phosphine, a tri (tributylsilyl) phosphine, a tri (trispentasilyl) phosphine, a tri (trihexylsilyl) phosphine, a tri (triheptylsilyl) phosphine, and a tri (trioctylsilyl) phosphine; and/or
the alkylphosphine having a side chain with a carbon number of four or more includes one or more of a tributylphosphine, a triheptylphosphine, and a trioctylphosphine.

8. The composite material of claim 1, wherein the inorganic semiconductor nanocrystal includes a doped metal element.

9. The composite material of claim 8, wherein:
the doped metal element accounts for 0.5-10% of the inorganic semiconductor nanocrystal in terms of mass percentage;
the doped metal element includes one or more of Mg, Mn, Al, Y, V, and Ni; and/or
the inorganic semiconductor nanocrystal includes at least one of a ZnO particle, a ZnS particle, or a SnO particle.

10. A composite material preparation method comprising:
dispersing a cationic precursor and an oil-soluble organic ligand into a first solvent and heating at a first temperature to obtain a first mixture, the cationic precursor including a metal halide;
dispersing an anionic precursor into a second solvent and heating at a second temperature to obtain a second mixture, the anionic precursor including an organic alcohol; and
while heating the first mixture at a third temperature, injecting the second mixture into the first mixture for a crystal growth of an inorganic semiconductor nanocrystal to obtain a composite material, the third temperature being higher than the first temperature and the second temperature.

11. The method of claim 10, wherein:
the metal halide includes:
one or more of chloride, bromide, and iodide of zinc;
one or more of chloride, bromide, and iodide of cadmium;
one or more of chloride, bromide, and iodide of tin; or
one or more of chloride, bromide, and iodide of germanium; or
the oil-soluble organic ligand includes one or more of an organic carboxylic acid with a carbon number of eight or more, an organic phosphoric acid with a carbon number of eight or more, a primary amine with a carbon number of eight or more, and a secondary or tertiary amine having a side chain with a carbon number of four or more.

12. The method of claim 10, wherein:
the first temperature is 110-190° C.;
the second temperature is 110-190° C.; and/or
the third temperature is 210-350° C.

13. The method of claim 10,
wherein the oil-soluble organic ligand is a first oil-soluble organic ligand;
the method further comprising:
after the crystal growth is completed, adding a second oil-soluble organic ligand during a cooling process so that the second oil-soluble organic ligand is bound on a surface of the semiconductor nanocrystal to obtain the composite material, the second oil-soluble organic ligand including a thiol with a carbon number of eight or more.

14. The method of claim 10, wherein the first mixture further includes a doped metal salt.

15. The method of claim 14, wherein the doped metal salt includes one or more of a Mg salt, a Mn salt, an Al salt, a Y salt, a V salt, and a Ni salt.

16. A quantum dot light-emitting diode comprising:
an anode,
a cathode, and
a laminate disposed between the anode and the cathode, including:
a quantum dot light-emitting layer disposed near the anode, and
an electron transport layer disposed near the cathode, a material of the electron transport layer including:
a particle including an inorganic semiconductor nanocrystal; and
a halogen ligand and an oil-soluble organic ligand bound on a surface of the particle.

17. The quantum dot light-emitting diode of claim 16, wherein the inorganic semiconductor nanocrystal includes at least one of:
a metal oxide particle selected from a ZnO particle, a CdO particle, a SnO particle, and a GeO particle; or
a metal sulfide particle selected from a ZnS particle, a SnS particle, and a GeS particle.

18. The quantum dot light-emitting diode of claim 16, wherein the halogen ligand includes one or more of a chloride ion, a bromide ion, and an iodide ion.

19. The quantum dot light-emitting diode of claim 16, wherein the oil-soluble organic ligand includes one or more of a linear organic ligand with a carbon number of eight or more, a secondary or tertiary amine having a side chain with a carbon number of four or more, a substituted or unsubstituted alkylaminophosphine, a substituted or unsubstituted alkoxyphosphine, a substituted or unsubstituted silylphosphine, and an alkylphosphine having a side chain with a carbon number of four or more.

20. The quantum dot light-emitting diode of claim 16, wherein the inorganic semiconductor nanocrystal includes a doped metal element.

21. The quantum dot light-emitting diode of claim 16, wherein the quantum dot light-emitting layer includes a water-soluble quantum dot.

22. The quantum dot light-emitting diode of claim 16,
wherein the electron transport layer is a first electron transport layer;
the quantum dot light-emitting diode further comprising:
a second electron transport layer disposed between the quantum dot light-emitting layer and the cathode, the second electron transport layer including a water-soluble electron transport material.

23. The quantum dot light-emitting diode of claim 22, wherein:
the quantum dot light-emitting layer includes a water-soluble quantum dot; and
the second electron transport layer is disposed between the first electron transport layer and the cathode.

24. The quantum dot light-emitting diode of claim 22, wherein:
the quantum dot light-emitting layer includes an oil-soluble quantum dot; and
the first electron transport layer is disposed between the second electron transport layer and the cathode.

25. The quantum dot light-emitting diode of claim 22, wherein:
the first electron transport layer is one of one or more first electron transport layers of the quantum dot light-emitting diode and the second electron transport layer is one of one or more second electron transport layers of the quantum dot light-emitting diode, the one or more first electron transport layers and the one or more second electron transport layers being arranged alternately; and
a total number of layers of the one or more first electron transport layers and the one or more second electron transport layers is in a range of 3-6.
